(19) United States
(12) Patent Application Publication
(10) Pub. No.: US 2006/0077724 A1
(43) Pub. Date: Apr. 13, 2006

(54) Disk array system

(76) Inventors: Takashi Chikusa, Odawara (JP); Yutaka Takata, Ninomiya (JP); Toshio Tachibana, Atami (JP); Takehiro Maki, Hadano (JP); Hirotaka Honma, Chigasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/000,072

(22) Filed: Dec. 1, 2004

(30) Foreign Application Priority Data
Oct. 12, 2004 (JP) 2004-297471

(51) Int. Cl. G11C 7/10

(52) U.S. Cl. 365/189.05

(57) ABSTRACT

The present invention enables to secure data reliability by avoiding data loss in an early failure period of an operation of a disk array system to which no particular measures have been taken conventionally. A controller of the disk array system stores first data to be stored in a HDD into a part of the region of one or more HDDs of an overall storage region composed of a plurality of HDDs and stores backup data of the stored first data into a part of the region of one or more HDDs in such a manner that they may be stored in the different HDDs. When there are no enough free space regions to store the first data in the overall storage region, the region in which the backup data is stored is overwritten to be used.

### CROSS-REFERENCE TO RELATED APPLICATION

The present application claims priority from Japanese Patent Application JP 2004-297471 filed on Oct. 12, 2004, the content of which is hereby incorporated by reference into this application.

### TECHNICAL FIELD OF THE INVENTION

The present invention relates to a disk array system for controlling data storage to a storage device such as a hard disk drive (hereinafter abbreviated as HDD) or the like. More particularly, it relates to a technology for avoiding loss of data stored in a storage region of the disk array system.

### BACKGROUND OF THE INVENTION

Conventionally, a computer system in which a disk array system is communicably connected to a host information processor such as a host computer of a customer (user) has performed a process to store data from the host to a storage region that the disk array system provides. It has been done particularly in the configuration in which a predetermined RAID system is employed to provide control in the disk array system. The user uses the disk array system in a variety of manners in accordance with importance of data to be stored in the storage region of the disk array system. Further, cost performance of a data capacity and reliability of data are in a trade-off relationship. Further, a failure rate of the system generally tends to follow a bathtub curve (failure rate curve), and it is high especially in an early period of an operation of the system. A conventional disk array system has no particular measures taken on it against an early period failure such as a failure in HDD. Further, the data accumulation rate of a disk array system usually increases as time passes by.

Further, as a technology for achieving redundancy of data to be stored in a storage device, a technology for storing data separately in a disk array is described in Japanese Patent Application Laid-Open No. 2000-148403.

### SUMMARY OF THE INVENTION

An early failure rate of a HDD is generally high, and further, a risk of data loss due to a HDD failure becomes higher when the number of HDDs included in the same RAID group in the case of a disk array system is increased. It is necessary to take measures for achieving data reliability by avoiding the data loss in the disk array system. However, if the disk array system is arranged with only data reliability taken into account, its cost performance is deteriorated.

Conventionally, as measures to avoid an early failure on the side of a disk array system, nothing has been taken other than achieving a predetermined level of redundancy. Further, on the side of manufacturer, it is actually difficult to take avoidance measures in terms of inspection space and facility costs. For these reasons, it can be said that the risk for the early failures of the products is high.

As for the RAID system for securing the redundancy, a data loss risk in an early failure period of the an operation of the system is by no means low even in the case of RAID 4 and RAID 5, which are well used. Even in the case of using the RAID 4 or RAID 5, data loss occurs if two HDDs become failure. Roughly speaking, especially in the case of the RAID 4 and RAID 5, in terms of data reliability, it can be said that the risk of data loss is rather high in an early failure period, low in a stable (intrinsic) failure period, and comparatively low in a wearout failure period.

Further, in the technology described in the above-mentioned Japanese Patent Application Laid-Open No. 2000-148403, the data is duplicated and then written in a group of storage devices for the improvement of performance and the data stored in one of the storage devices is stored in the others. In this point, this technology is in common with the present invention but whose processes are not identical to those of the present invention.

In view of the above, the present invention has been developed and an object of the present invention is to provide a technology capable of securing data reliability by avoiding data loss in an early failure period of an operation of a disk array system which has not been particularly considered.

The typical ones of the inventions disclosed in this application will be briefly described as follows.

For the achievement of the above-described object, a disk array system of the present invention has a storage device such as a HDD and a controller for controlling data storage to a storage region of the storage device, and it inputs/outputs the data in accordance with a request from a host information processor such as a host computer of a user connected through communication means and is provided with the following technological means.

The present invention provides means for securing data reliability in an early failure period of an operation of the disk array system because a rate of occurrence of failure in the early failure period is high in a period when a data accumulation rate of a HDD is low. As this means, an unused (free space) region of the storage device, that is, a region not used for data storage is utilized for the data backup, in other words, for storing copied data. By doing so, data loss due to a failure in the early failure period of the operation of the disk array system can be prevented.

In the disk array system of the present invention, the controller utilizes a large free space region of a storage region of the storage device to store data to be stored in the storage device (hereinafter referred to as first data) into a first storage region which constitutes a part of storage region of one or more storage devices among the overall storage region of a plurality of storage devices, and when the first data is stored, the controller stores backup data of this first data into a second storage region which constitutes a part of storage region of one or more storage devices so that the backup data of the first data is stored in a storage region different from that of the first data. The first data is user data which is inputted/outputted between the host information processor and the storage device, that is, write data and the like transmitted from the host information processor and received by the controller. As far as there is a free space region in the overall storage region or up to a predetermined capacity, the backup data is stored under the condition that a top priority is given to the ordinary storage of the first data. If there is no free space region to store the first data or a capacity of the free space region becomes less than a predetermined value in the overall storage region, the controller gradually releases the second storage regions in which the backup data is stored and uses them to store the first data by overwriting it. When the first data and the backup data are written in the storage device, the controller writes the first data to be stored in one or more storage devices so that the backup data is stored in the storage device different from that of the first data.

According to a typical process procedure, the controller writes write data from the information processor to the first storage region, the backup data is written to the second storage region immediately or later when the remaining free memory in a cache memory of a controller is many. Further, when the first data stored in the storage device is read in response to the request from the information processor, the controller can read both of the first data in the first storage region and the backup data in the second storage region and also utilize them for data recovery. That is, the controller can read just one of the first data or the backup data and then read another data when data recovery is necessary. Alternatively, the controller can read both of them concurrently from the beginning.

For example, a part of the region in the unused regions consisting of 50% or more of a group of the storage devices is used as a backup data storage region. Note that, in the storage region of each storage device, if the first data and the backup data having the same storage unit size are stored and each data uses about 50% of a storage capacity of the storage device, all the regions are used and there is no free space region therein. It is also preferable that a predetermined capacity in the whole capacity of the storage region is preserved as a region to store the backup data.

Further, the controller divides (stripes) the first data to be stored into the storage device and performs parity process such as parity generation and parity check in order to provide control in accordance with the RAID control system, for example, the RAID 3, 4, or 5. The controller stores the striping data of the first data created by the RAID control, that is, non-parity data or parity data to a first storage region which constitutes a part of the storage region of one or more storage devices among the overall storage region of the plurality of storage devices, and when the first data is stored, backup data of the striping data is stored into a second storage region which constitutes a part of the storage region of one or more storage devices so that this backup data is stored in a region different from that of the striping data, that is, at a location in an adjacent one of the storage devices. The controller stores a plurality of divided data made by the data striping process into plural storage devices as their respective storage destinations. Further, when the striping data is read, the controller reads the striping data from the storage regions of the respective storage devices which constitute the first and second storage regions, thus acquires the normal first data described above. For example, in the RAID group of the plurality of storage devices, the controller stores the first data, that is, corresponding to backup data of the striping data into locations in an adjacent one of the storage devices in accordance with the RAID control. In the allocation of storage devices of the first data and the backup data, the first data and the backup data can be stored at predetermined fixed related locations or at optional locations depending on a data storage situation under the conditions that their respective storage devices to be the storage destinations are different from each other.

Further, it is also preferable that the controller can provide a region for storing the first data (referred to as a data region) and a region for storing the backup data (referred to as a backup region) in the overall storage regions in advance. For example, as the setting, a predetermined capacity, for example, 50% of the overall storage region is preserved as each of the data region and backup region, or 75% is preserved as the data region and 25% is preserved as the backup region. The controller continues to store the backup data as well as the first data until the backup region is used up, and when the data region is used up to store the first data, it starts to use the backup region to store the first data. For example, if 25% of the overall region is used as the backup region, the data region and the backup region are used to store the data at first, and when the backup region is used up, the first data is stored in the data region without backup data until it is used up, and thereafter, when the data region is used up, the first data is overwritten in the backup region.

Further, in order to store the first data and the backup data, the controller divides the overall storage region comprised of the plurality of storage devices into units of storage region each having a predetermined size, and it holds and manages the correlation by means of address conversion between addressees of these regions (referred to as divided region) and an address system in the storage device such as LBA in the HDD by using management variables. By means of this management of the divided regions, the processes to store the first data and the backup data are sequentially performed in units of the divided region so as to actively secure a large free space region in the overall storage region.

Further, if a data read error occurs due to the failure of any one of the plurality of storage devices or the storage region in which the first data or the backup data is stored, the controller reads the backup data or the first data in the corresponding storage device or storage region to recover the error data. For example, if an error occurs due to a failure of the first data stored in any one of the storage devices, the backup data stored in its adjacent storage device is read to recover the defective data. In this case, unless both of a storage device in which the first data is stored and another device in which its backup data is stored become failure simultaneously, the data can be recovered even if two storage devices become failure. Especially in the case of RAID 3, 4, 5, or the like, the data can be recovered only by reading this data without performing the process using parity data read from the parity-data storage device.

Further, as a first backup mode, the controller provides such control as to allocate the overall storage regions sequentially from the top region of the data region to store the first data and allocate them sequentially from the last region of the backup region to store the backup data, and when the data region is used up, the backup data is sequentially released from the more recent ones which are stored in the backup region.

Further, as a second backup mode, the controller provides such control as to allocate the overall storage regions sequentially from the top region of the data region to store the first data and allocate them sequentially from the top region of the backup region to store the backup data, and when the data region is used up, the backup data is sequentially released from the old ones which are stored in the backup region.

Further, when inputting or outputting the first data or the backup data from/to the plurality of storage devices, the controller prevents the accesses from being concentrated on a particular one of the storage devices by performing access distribution, for example, alternating accesses between the storage destination storage devices of the first data and those of the backup data.

The effect obtained by the representative one of the inventions disclosed in this application will be briefly described as follows.

According to the present invention, it is possible to secure data reliability by avoiding data loss in an early failure period of an operation of a storage device in a disk array system to which no particular countermeasures have been taken so far. Even in the case where a failure rate in an early period of a HDD surpasses a redundancy of a disk array system like in a conventional case of a double failure, the user data is protected by the backup method of the present invention and the robustness of the system can be improved.

### BRIEF DESCRIPTIONS OF THE DRAWINGS

FIGS. 1A and 1B are diagrams showing external appearance of a hardware configuration of a disk array system according to a first embodiment of the present invention;

FIG. 2 is a functional block diagram for showing a system configuration related to a backup method in the disk array system of the first embodiment of the present invention;

FIG. 3 is a diagram showing array variables (region management table), which constitute information held by a controller to manage regions in accordance with a backup method in the disk array system of the first embodiment of the present invention;

FIG. 4 is an explanatory diagram of a first backup mode and a second backup mode in the backup method in the disk array system of the first embodiment of the present invention;

FIG. 5 is a flowchart for showing the process to write data to a HDD in the disk array system of the first embodiment of the present invention;

FIG. 6 is a flowchart for showing the process to read data from the HDD, especially, the usual process when the HDD has no failure in the disk array system of the first embodiment of the present invention;

FIG. 7 is a flowchart for showing the process to read data from the HDD, especially, the process when the HDD has a failure in the disk array system of the first embodiment of the present invention;

FIGS. 8A to 8C are explanatory diagrams of a process model for the data recovery in the case of HDD failure in the disk array system of the first embodiment of the present invention;

FIG. 9 is a flowchart for showing the process to perform data recovery from an error state corresponding to the case of FIG. 8C in the disk array system of the first embodiment of the present invention;

FIG. 10 is a diagram showing a setting screen example and a setting example about the backup method of in the disk array system of the first embodiment of the present invention;

FIG. 11 is an explanatory diagram showing an example of an internal operation that corresponds to the setting example shown in FIG. 10 in the disk array system of the first embodiment of the present invention;

FIG. 12A is a graph for showing a relationship between a typical failure rate curve (Bathtub curve) and a data accumulation rate (capacity usage rate) in a disk array system, and FIG. 12B is a table for showing data reliability in accordance with a RAID system and a device operation period;

FIG. 13 is an explanatory diagram of an outline of the backup method in a disk array system of a second embodiment of the present invention;

FIG. 14 is a diagram showing an example of the setting screen in the case where the process in which the data region and the backup region area arranged so that they are crossed to each other in one LU and another LU in the disk array system of the second embodiment of the present invention;

FIG. 15 is a flowchart for showing a setting procedure for the process in which the regions in a pair of LUs are arranged so that they area crossed to each other, especially, a backup LU setting procedure in the disk array system of the second embodiment of the present invention;

FIG. 16 is an explanatory diagram of an outline of the backup method in a disk array system in a third embodiment of the present invention;

FIG. 17 is a flowchart for showing the process compatible with a backup method in the disk array system of the third embodiment of the present invention;

FIGS. 18A to 18D are explanatory diagrams of a data recovery procedure and a concept of internal process in the case where a HDD double failure has occurred in the disk array system of the third embodiment of the present invention;

FIG. 19 is a flowchart for showing a process procedure corresponding to FIG. 18 in the case where two HDDs have encountered a failure in a RAID group in the disk array system of the third embodiment of the present invention;

FIG. 20 is a functional block diagram of a disk array system of a fourth embodiment of the present invention;

FIG. 21 is a diagram showing an example of an important data selection screen in the disk array system of the fourth embodiment of the present invention; and

FIG. 22 is a flowchart for showing a procedure for setting important data specification information in the disk array system of the fourth embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

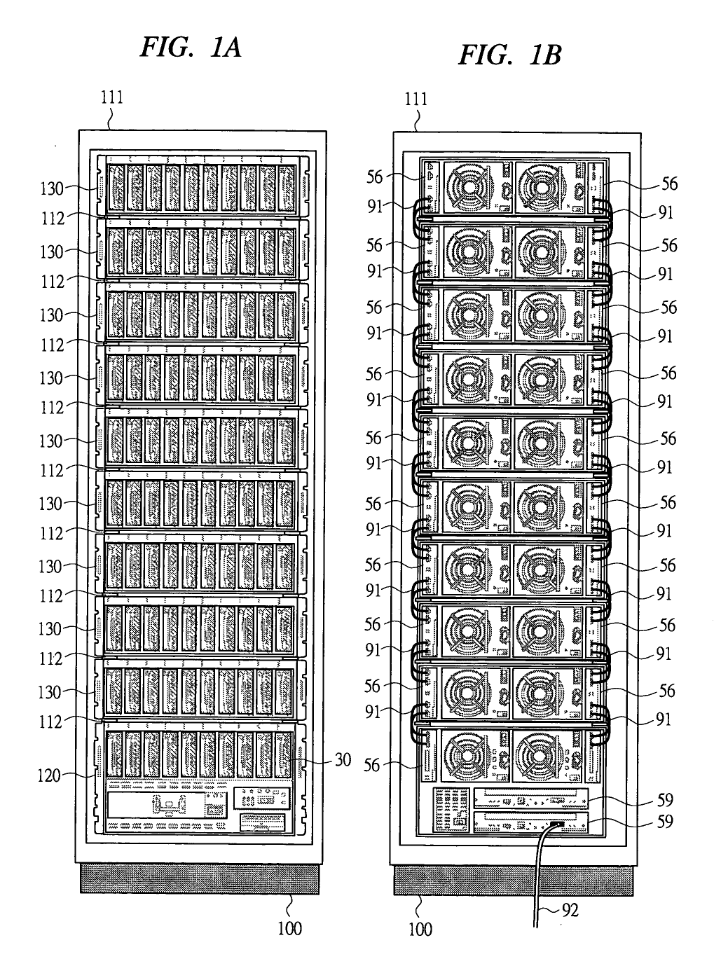

FIGS. 1 to 12 are diagrams for describing a disk array system of the first embodiment of the present invention. A disk array system of the first embodiment has means for storing backup data of first data to be stored to the HDD into a free space region of other HDD in a period such as an early failure period of device operation when a HDD has a large free space region. The first embodiment provides a basic configuration and processes of a backup system by using that means.

<Hardware Configuration>

First, overall configuration of the disk array system of the first embodiment will be described. After that, characteristic processes in the present invention will be described. FIGS. 1A and 1B show external appearance of the hardware configuration of the disk array system according to the first embodiment. FIG. 1A shows a front of the system and FIG. 1B shows the rear thereof. The disk array system 100 has a rack frame 111 as a base and several stages of mount frames 112 arranged vertically inside the rack frame 111, and a base chassis 120 (referred to as disk array control chassis) and expansion chassis 130 (referred to as HDD chassis) are mounted along the mount frames 112 in such a manner that they can be pulled out. The system 100 has the one base chassis 120 mounted on the lowest stage and a plurality of expansion chassis 130 that can be mounted on the upper stages. Each of the chassis is provided with a board (circuit board) and a unit that provide various functions of the system 100. The base chassis 120 contains a controller board 59 or the like which constitutes a controller 10 of the disk array system. The expansion chassis 130 contain a plurality of HDDs 30 and it is possible to add the expansion chassis as required.

On the front side of the system, a region is allocated in which a plurality of base chassis 120 and the expansion chassis 130 can be arrayed and mounted in the form of units each having the integrated HDD 30 and canister or the like. At each of the mounting positions, the HDD 30 can be mounted/unmounted. Further, a battery unit functioning as a backup power supply, a display panel that displays a state of the devices, a flexible disk drive for a program load and the like are arranged on the front side of the base chassis 120.

On the rear side of the system, a power supply controller board 56, a power supply unit, and the like are arranged in the base chassis 120 and the expansion chassis 130. Further, a controller board 59, a cooling fan unit, and the like are arranged on the rear surface of the base chassis 120.

In each of the chassis, a backboard is provided to connect various components and each of the boards, units and the plurality of HDDs 30 are connected to the backboard. The components are communicably connected through the wiring over the backboards.

The controller board 59 controls the data storage to the HDD 30 based on an instruction from an information processor 300 or the like. The controller board 59 is mounted with a communication interface (channel control section) with, for example, an external device such as the information processor 300, a cache memory, a shared memory, a communication interface (disk control section) with the HDD 30, and a circuit functioning to provide control in accordance with the RAID system and monitor a state of the HDD 30. Note that such functions as the communication interface and the cache memory can be mounted on a board different from the controller board. Also, two controller boards 59 are mounted for redundancy in order to keep the security in the control of the HDDs 30 in the base chassis 120.

The communication interface with the information processor 300 of the controller 10 is provided with, as an external connector to the information processor 300, one such in conformity to a predetermined standard such as SAN (storage region network) constituted of a fiber channel (FC) protocol, LAN (local area network) constituted of a protocol such as Ethernet (registered trademark), or an SCSI. The disk array system 100 is connected to the information processor 300 through a communication cable 92 that is connected to this external connector.

The power supply controller 56 connects the chassis to each other and provides system control such as power supply over the chassis as well as control of the HDDs 30. A communication cable 91 is connected to a connector of the power supply controller boards 56 and the power supply controller boards 56 are connected via the communication cable 91. The power supply controller board 56 is communicably connected to the plurality of HDDs 30 through a communication path in accordance with a predetermined protocol. The power supply controller board 56 is mounted with a circuit to monitor the states of an AC/DC power supply and the HDD 30 and control the power supply to the HDD 30 besides a disk control section that controls the HDD 30. Note that functions of the power supply controller board 56 may be provided on the side of the controller board 56.

The power supply unit is provided with an AC/DC power supply and the like and supplies the DC power to the inner components of the chassis such as the HDD 30 and the boards. The power supply unit is connected to the power supply controller board 56 and supplies power to the HDDs 30 based on a signal from the power supply controller board 56. Note that two pairs of the power supply controller 56 and the power supply unit are mounted to each of the chassis in order to keep the security of power supply to the chassis.

The HDD 30 is a storage device provided with, for example, a 3.5-inch magnetic disk of the constant start stop (CSS) system or a 2.5-inch magnetic disk of the load/unload system. The 3.5-inch magnetic disk has a communication interface such as SCSI1, SCSI2, SCSI3, FC-AL (Fibre Channel-Arbitrated Loop), parallel ATA, or serial ATA. Similarly, the 2.5-inch magnetic disk has a communication interface such as parallel ATA or serial ATA. The 2.5-inch magnetic disk and the 3.5-inch magnetic disk serving as the HDDs 30 which are mounted and connected to the chassis are different from each other not only in terms of communication interface but also in terms of I/O performance, power consumption, lifetime, and the like. The 2.5-inch magnetic disk is inferior to the 3.5-inch magnetic disk in I/O performance and lifetime but less power consumption than it.

<System Configuration>

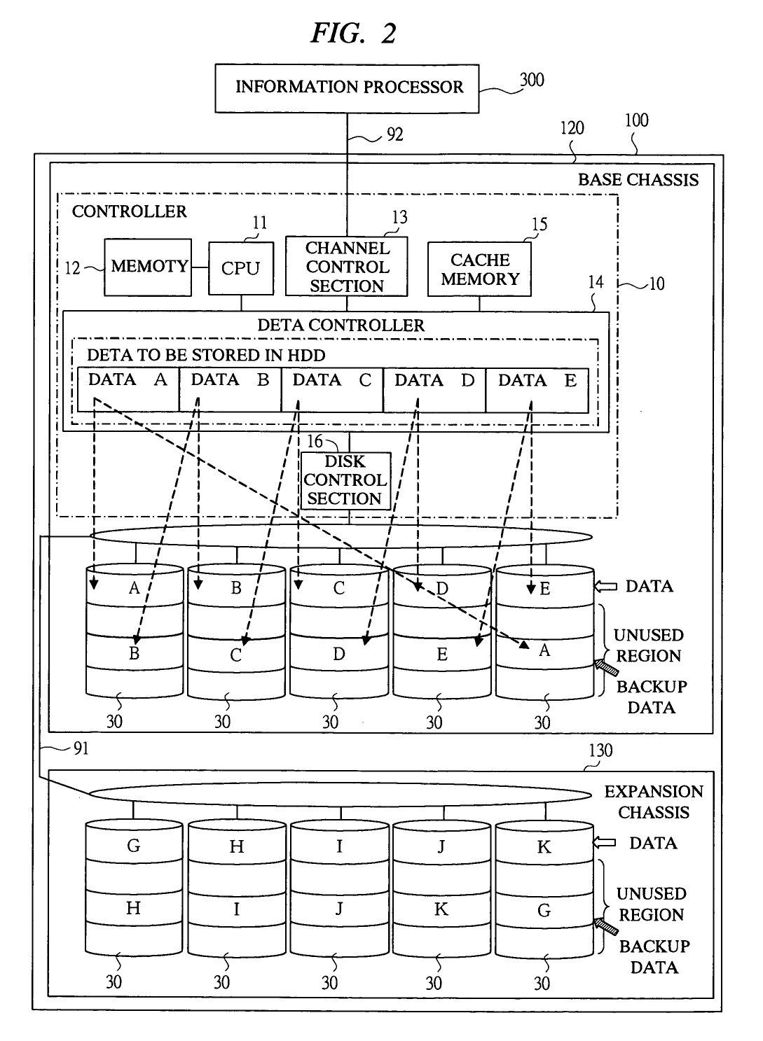

FIG. 2 is a functional block diagram showing a system configuration related to a backup method in the disk array system 100 of the first embodiment. In this diagram, an outline of the backup method is also shown.

In this configuration, the controller 10 of the disk array system 100 and the information processor 300 that serves as a host are connected to each other through a channel control section 13, the communication cable 92, and the like in a computer system that comprises the disk array system 100. They are communicably connected through the channel control section 13 and a communication processing section of the information processor 300 in accordance with a standard such as FC or Ethernet (registered trademark).

The disk array system 100 has the controller 10, the HDD 30, and connection parts such as a bus (communication line) and a port for connecting these. The controller 10 and a group of the HDD 30 are provided in the base chassis 120 and a group of HDDs 30 is provided in one or more expansion chassis 130 connected to the base chassis 120. The above-described components are connected in such a manner that this connection may have redundancy among the information processor 300, the controller 10, and the HDD 30. For example, such a configuration is possible that the multiple controllers 10 or the like are provided and the multiple components on a data path from the information processor 300 to the HDD 30 are provided. By doing so, it is possible to achieve the fail-over in which the path is switched to another path to continue the processes even if one path has a failure and a load distribution. The multiple components to be provided have almost the same configuration.

The information processor 300 may be a personal computer of a user, a workstation, or a mainframe computer. The information processor 300 is provided with a program to utilize the disk array system 100 and a communication interface or the like for communicating with the disk array system 100 in accordance with the FC. The information processor 300 issues an instruction (input/output request) for performing a data read/write operation to a storage region provided by the HDD 30 to the disk array system 100. In an access from the information processor 300 to a storage volume in the disk array system 100, a data access request in units of a block which is a data access unit on the side of the HDD 30 is transmitted to the channel control section 13 of the controller 10 in accordance with a communication protocol.

The information processor 300 is provided with a CPU, a memory, a port, an input device, an output device, a storage device, a storage medium reader, and the like. When the CPU executes a program in the memory, various functions are realized. The memory stores an application program, a utility program, and the like. The port is connected to a network for communication with the disk array system 100 or other external device such as the information processor 300. The input device is a keyboard or a mouse for operations of the user. The output device is a display or the like for displaying information. The storage device is a semiconductor storage device or a HDD, for example. The storage medium reader is a device for reading a program or data stored in a storage medium. The read program or data is stored in the memory or the storage device. The storage medium is, for example, a flexible disk, a CD-ROM, or the like.

An application program in the information processor 300 controls on-line process that utilizes a function provided by the disk array system 100. The information processor 300 executes the application program as appropriately accessing data stored in a storage volume in the disk array system 100, thereby providing a variety of information processing services. The information processing services include, for example, an automatic teller system in a bank.

A utility program in the information processor 300 is used to utilize a variety of functions provided by the disk array system 100 and is provided with a function to issue a variety of requests such as read/write commands for performing data input/output operations to the HDD 30. The utility program also has a variety of maintenance/management functions especially in the case where the information processor 300 serves as a management server having a role of performing maintenance/management of the disk array system 100.

The controller 10 is mounted on the controller board 59 and has a CPU 11, a memory 12, the channel control section 13, a data controller 14, a cache memory 15, a disk control section 16, and connection sections for connecting these. It is possible to provide more than one channel control sections 13 and the disk control sections 16 to realize a multiple configuration. Each of the controllers 10 is connected to an outside through the channel control section 13. Further, the controller 10 is connected through the disk control section 13 and the bus to a group of the HDDs 30 in each of the chassis. Connection between the chassis corresponds to the communication cable 91.

The controller 10 provides various kinds of control related to data storage in accordance with a request received from the information processor 300. For example, it receives a read command or a write command from the information processor 300 to perform a data input or output process such as a read or write operation to a storage volume on the HDD 30. Further, the controller 10 transmits various instructions to and receives them from the information processor 300 to manage the disk array system 100. It can set a RAID group for a group of the HDDs 30 to set a logical device (LDEV) and a logical unit (LU) in the RAID group and also has a function to provide control in accordance with a predetermined RAID system.

The CPU 11 uses the memory 12 to execute a control program in the controller 10 to realize various functions of the controller 10. The memory 12 stores various programs and data.

The channel control section 13 is a communication processing section which is connected to the information processor 300 and provides a communication function in accordance with the FC protocol. The channel control section 13 communicates via a port or protocol section with a communication processing section on the side of the information processor 300 or other disk array system 100 or the like. Further, the channel control section 13 is connected to the data controller 14 and performs data read/write operations from and to the cache memory 15.

The data controller 14 is an LSI which is connected to the CPU 11, the channel control section 13, the cache memory 15, and the disk control section 16 and performs data communication and data processing between these components. The data controller 14 performs read/write operations of the data to be processed from and to the cache memory 15.

The cache memory 15 is used to store the data to be processed, especially, data to be transferred between the information processor 300 and the HDD 30. For example, during a normal access, the channel control section 13 stores write data or the like via the data controller 14 into the cache memory 15 in response to a data input/output request such as a read/write request from the information processor 300. The disk control section 16 performs input/output processes corresponding to a command to the cache memory 15 via the data controller 14 in accordance with an instruction from the CPU 11.

The disk control section 16 is connected via the bus to the data controller 14 and provides control including data input/output processes to the HDD 30. Further, the disk control section 16 performs read/write operations via the data controller 14 to the cache memory 15. The disk control section 16 performs communication through a communication line in accordance with the FC-AL system or the like that connected to the HDD 30 in a loop. All of the plurality of HDDs 30 are communicably connected via the disk control section 16 and the bus to the controller 10.

The disk control section 16 performs the process to transfer the user data from the cache memory 15 and write it to a region of the HDD 30 during the data write process. Further, it performs the process to read user data from the region of the HDD 30 and transfer it to the cache memory 15 during data read process. In the read/write process, the disk control section 16 performs the address conversion of the data to be read or written, thereby obtaining a internal address of a location in the HDD 30 to be accessed, that is, an LBA.

Further, the above-described configuration in the controller 10 is a mere example. Although the cache memory 15 is provided independently of the channel control section 13 and the disk control section 16, the configuration is not limited to it, and the configuration in which memories are provided respectively for each components including the channel control section 13 and the like is also available.

Data is stored in a storage volume provided by one or more HDDs 30, that is, in a physical storage region on a disk or a logical storage region which is set in the physical storage region. A region accessible from the information processor 300 and in which user data is stored, a region used to store the system data for system control in the disk array system 100 and the like are provided as the storage volume set on the HDD 30 and they can be set and preserved as required. The user data is included in the data whose backup data is stored in accordance with the backup method of the present invention in order to secure data reliability. Not only the user data from the information processor 300 but also system data of an OS or applications described later can be employed as the data to be backed-up by the present backup method. Further, the storage device which is connected to the controller 10 is not limited to the HDD 30, and various devices such as a flexible disk device or a semiconductor storage device is also available. The disk control section 16 and the HDD 30 can be connected to each other directly or through a network or a switch.

The HDD 30 has an LBA (logical block address) as an internal address for identifying the location in a physical storage region on the disk where the data is to be written to or read from. For example, in the HDD 30, by specifying location information such as a cylinder or a track, the data can be written to or read from an optional location on the disk as a random access. When a data input/output operation is performed to a storage volume, the disk control section 16 performs the process to convert from a logical address to an internal address, that is, an LBA on the disk.

Further, to the disk array system 100, it is possible to connect a management device for maintenance, management, or the like of the disk array system 100 and any other devices such as a magnetic tape device for recording the backup of data stored in the HDD 30 directly or via a network. Further, it is also possible to realize the remote control by communication between one disk array system 100 at a location (primary site) and another disk array system 100 at another location (secondary site) far from the primary site. For example, it is possible to perform the Remote copy for data conservation or the like between the disk array systems 100.

By using a management program installed in the information processor 300 or a management terminal (SVP: service processor) provided in the disk array system, it is possible to make various settings and perform maintenance/management of the disk array system 100. More specifically, by using the management program, it is possible to set the physical disk configuration, a logical device, and a logical path in the HDD 30 and to install a program which is executed by the channel control section 13 and the like. As the settings of the physical disk configuration, for example, the decrease or increase of the number of the HDDs 30 and the change of the RAID configuration can be performed. Further, it is also possible to perform the check of an operation state of the disk array system 100 and identification of a faulty part location.

Similar to the hardware configuration of the information processor 300, the hardware configuration of the management terminal (SVP) includes a CPU, a memory, a port, an input device, an output device, a storage device, and the like in the case of a PC. When the CPU executes a control program in the memory, various functions for maintenance/management are realized. The memory stores the control program and various kinds of information related to maintenance/management. For example, a port of the management terminal is connected to the controller 10, and thus, the management terminal can communicate with the channel control section 13 and the like.

<Backup Method>

The controller 10 shown in FIG. 2 stores the target first data to the HDD 30 through the process by the disk control section 16. In this operation, the controller 10 performs such process as to store the first data in a certain region of an overall storage region provided by a RAID group constituted of a plurality of HDDs 30 and store the backup data of the first data in an unused region in such a manner that its storage destination HDD 30 is different from that of the first data. In the storage region of one HDD 30, the first data and the backup data of other first data stored in another HDD 30 coexist.

In the first embodiment, as an example of RAID control, the control in which a first data from a host is striped and stored into a plurality of HDDs 30, for example, the control in accordance with RAID 0, 3, 4, 5, or the like is conducted. Under the process control especially by the data controller 14 in the controller 10, the control in which user data from the information processor 300 to be stored in the HDD 30 is striped and stored into a storage region provided by the plurality of HDDs 30 which constitutes a RAID group is conducted. Simultaneously, the process to store the backup data of the stored user data in a storage region and to store the respective striping data in a storage region of another HDD 30 of the same RAID group is performed.

FIG. 2 shows a state where the striping data are stored in the HDDs 30 which constitutes the RAID group in accordance with the RAID control in the disk array system 100. As the RAID control, the controller 10 is provided with a function to stripe the user data from the host and input them to or output them from the HDDs 30. For example, five physical HDDs 30 connected to the base chassis 120 constitute one RAID group, a logical storage volume in accordance with the RAID control is set on this RAID group, and the first data composed of striping data A to E is stored in this storage volume. Similarly, five physical HDDs 30 connected to the expansion chassis 130 constitute a RAID group, a storage volume in accordance with the RAID control is set on this RAID group, and the first data composed of striping data G to K is stored in this storage volume. The storage volume set on the RAID group corresponds to a logical unit (LU) or a logical device (LDEV). When the first data is striped by the striping process and the striping data are stored in the HDDs 30, the controller 10 stores the backup data of each of the striping data into the storage regions of the same RAID group. In FIG. 2, for example, the data controller 14 performs the process to store the backup data of the first data composed of the data A to E in unused regions for user data storage that exist in the same RAID group. At this time, in order to secure the redundancy, the striping data A to E are stored in the HDD 30 which is different from that in which the backup data A to E are stored. Note that since the first data has the same contents as its backup data, they are denoted by the same symbols. For example, from storage locations of the user data, that is, the striping data A to E, the storage locations of the backup data thereof, that is, the backup data A to E are shifted to each adjacent HDD 30 and stored therein. For example, as for the striping data, the backup data B of the striping data B is stored in an unused region of the HDD 30 in which the striping data A is stored, while the backup data C of the striping data C is stored in an unused region of the HDD 30 in which the striping data B is stored.

Further, in contrast to the case of backup in accordance with RAID control, in a simpler case, the user data a may be stored in two HDDs #0 and #1. In this case, the controller 10 stores the user data a in one HDD #0 and its backup data a′ in a free space region of the other HDD #1. Further, in the case of storing the user data a and b in the two HDDs #0 and #1, the controller 10 stores the user data a in one HDD #0 and its backup data a′ in a free space region of the other HDD #1, and stores the user data b in the HDD #1 and its backup data b′ in a free space region of the HDD #0. More specifically, the two HDDs 30 are paired to store the first data and its backup data in the free space regions of the respective HDDs 30 in such a manner that the storage locations thereof are arranged so that they area crossed to each other.

Note that in the case where the control in accordance with RAID 3, 4, 5, or the like is conducted to store parity data, some of the striping data provide the parity data. For example, the data E serves as the parity data for the non-parity data A to D. For example in the control in accordance with RAID 5, the controller 10 performs striping and parity generation/addition processes of the user data as the first data sent from a host and then performs the process to concurrently write striped data and parity data to the HDDs 30 of the RAID group. Further, the controller 10 performs the process to concurrently read the striped data and the parity data of the fist data stored after being striped in the RAID group, perform the parity check to confirm whether the read data is normal by using the parity data, and return the recovered ordinary data to the host.

A procedure of the process related to the backup method in the disk array system 100 of the first embodiment is outlined as follows. The backup method in the first embodiment can be applied to the RAID systems of RAID 3, 4, 5, and 0.

(1): In a period when first data such as the user data occupies, for example, less than 50% of the overall storage region of a plurality of HDDs 30, that is, in a period when there is a free space region, the controller 10 stores the first data as usual and also stores the backup data of this first data in a free space region of any other HDD 30. When the data is store after being striped, the controller 10 stores the striping data into the corresponding HDDs 30 in the group and stores backup data corresponding to these striping data into a free space region of any other HDD 30 in the same group. However, when the occupation ratio of the first data in the overall storage region becomes near 50%, that is, when the storage region is used up by the first data and the backup data, the backup data region is used to store the usual first data by overwriting it. In this operation, the backup data is lost gradually.

(2): When reading the first data stored in a HDD 30, in the case of a data read having the backup data, since the target data and its backup data having the same contents are present in different HDDs 30, the controller 10 can utilize not only the normally stored first data but also the corresponding backup data. That is, the controller 10 accesses one or both of the first data and its backup data stored in the HDDs 30 to acquire the target data. Further, it also can read and acquire the target data from one of the HDDs 30 which has a shorter waiting time.

(3): If reading of target first data fails due to a failure of the HDD 30 in a group of HDDs 30 in which first data and backup data are stored, the corresponding backup data stored in the other HDD 30 free from the failure is read so as to recover the defective data. Similarly, if reading of target backup data fails, the corresponding first data is read from the other HDD 30 so as to recover the first data. If an error occurs due to a failure of one HDD 30 in the group, the defective data can be recovered only by copying the backup data stored in the other HDD 30. Further, if data cannot be recovered only by copying the backup data due to a failure of two or more HDDs 30 in the same group, the data can be recovered by using the ECC correction in combination if RAID 3, 4, or 5 is employed.

The above-described data and backup data storage processes are automatically performed in a period when a used storage space of the storage region of the HDD 30 is small, especially in an early failure period of an operation of the disk array system 100, and the first data and its backup data are sequentially stored and accumulated in larger free space regions, respectively. For example, the first data and the backup data are accumulated in the different storage regions in the overall storage region. Even in the case where a system such as RAID 0 that originally has no redundancy is employed, the data recovery can be achieved by using the backup data, and thus, the almost same data reliability as that in the case where RAID 1 is employed can be obtained. In the early failure period of the system operation when a data accumulation rate is low and a failure rate is high in the HDD 30, it is possible to secure the data reliability by performing the backup method of the present invention. After that, as time shifts to a stable period of the system operation, that is, a stable failure period when the failure rate is low, the data accumulation rate increases and the necessity of holding backup data decreases relatively. Therefore, such regions storing the backup data among the overall storage regions are gradually released and used for its original usage, that is, data storage by overwriting the first data.

<Region Management>

For the processes in the present backup method, when storing first data and backup data to the overall storage region provided by a plurality of HDDs 30, the controller 10 divides the overall storage region into storage region units each having a predetermined size and manages them. Then, the controller 10 consecutively performs the processes to store the first data and the backup data into each of these divided and managed regions (referred to as divided region r). In this manner, consecutive regions as large as possible are formed without making a small unused region in the overall storage region, the first data and the backup data are respectively stored in different data storage region (referred to as data region) and backup data region (referred to as backup region), and each data is collectively stored in a plurality of consecutive divided regions r. The divided region r is a unit of the logical storage region and is different from a storage region that corresponds to an LBA, which is an address system in the HDD 30. Further, by managing the divided regions r, the used capacities of the overall storage region by the respective first data and the backup data are checked and managed. Hereinafter, the management of the divided regions r and the used capacity is referred to as region management.

In the region management, the controller 10 performs LBA conversion to correlate an LBA, which is an address of a storage region of the HDD 30, and an address of the divided region r with each other. Then, resultant correlation information is held in the controller 10 so that it is referenced as required. This LBA conversion is mutual conversion between an LBA to which data is stored in an original case, that is, in the case where region management is not performed and an LBA indicating the location of the divided region r, to the storage region of the HDD 30. In the case of the data storage, the controller 10 performs the process to store the target data not to the location of an LBA of an original data storage destination specified on the basis of a command from the host but to a location of a divided region r obtained through the LBA conversion.

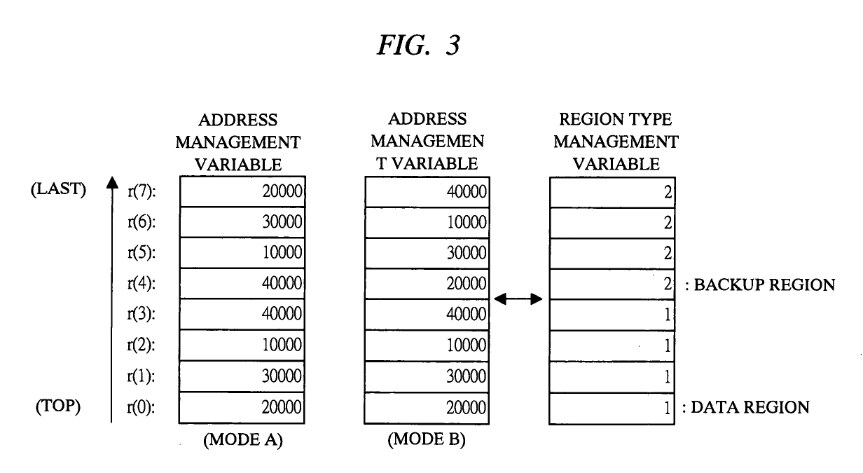

FIG. 3 shows a configuration example of array variables (referred to as region management table), which constitute control information held by the controller 10 to manage the regions. In this region management table, an address management variable and a region type management variable are provided as the management variables. Stored values are mere examples. An address management variable is used to store correlation information in the LBA conversion. That is, the controller 10 stores an LBA value to be an original data storage destination into an address management variable corresponding to each divided region r. In other words, an LBA value that provides the original data storage destination is assigned with each divided region r for storing first data or its backup data by the LBA conversion.

Further, the controller 10 manages control information so that the storage data type can be distinguished as to whether data to be stored in each divided region r is usual first data or its backup data. That is, a region type management variable is used to store the region type information for distinguishing a type of the data to be stored in each divided region r. For example, the region type information distinguishes a data region in which usual first data such as user data from a host is stored as “1” and a data region in which its backup data is stored as “2”. When inputting data to or outputting it from the HDD 30, the controller 10 performs LBA conversion and also references/updates these management variables to perform the processes.

An arrangement of address management variables shown in FIG. 3 corresponds to that of divided regions r in a storage region of the HDD 30. For example, FIG. 3 shows address management variables {r(0) to r(7)} that respectively correspond to eight divided regions r in one HDD 30. The left-side address management variables indicate an example that corresponds to a later-described first backup mode (mode A) and the right-side address management variables indicate an example that corresponds to a later-described second backup mode (mode B). An order in which backup regions are arranged is reversed from each other in the modes A and B. For example, as for the left-side address management variables that correspond to the mode A, an LBA value “20000H” (hexa-decimal) is stored in a bottom address management variable r(0) that corresponds to a top one of all of the divided regions r, and “1” that indicates a data region is stored in the corresponding region type management variable. Furthermore, the same LBA value “20000H” is stored in a top address management variable r(7) that corresponds to a last one of all of the divided regions r, and “2” that indicates a backup region is stored in the corresponding region type management variable. That is, the top divided region r of the overall storage region is assigned as a data region to the LBA value “20000H” which provides an original data storage destination and the last divided region r is assigned as a backup region. When the host issues a request for data storage to a location of LBA value “20000H” in overall unused storage regions, the controller 10 performs LBA conversion to assign the top divided region r of all the divided regions as a data region and the last divided region r of them as a backup region and stores the LBA value “20000H” and the respective region type information values “1” and “2” in management variables that correspond to these divided regions r.

By conducting the region management in such a manner, the controller 10 performs efficient storage processes of the first data and the backup data for each of the divided regions r, and thus, a used capacity of the overall storage regions and a type of data stored can be controlled. Further, a divided region r to be processed can be optionally selected, and therefore, it is possible to reduce the time required to recover data to a spare disk by utilizing the first data or the backup data.

<Backup Mode>

According to the backup system of the first embodiment, the following first and second backup modes are available as modes of the backup processes relating to the arrangement of the first data and its backup data to be stored in an overall storage region provided by a plurality of HDDs 30. In these modes, the first data and the backup data are stored with using each of the divided regions r as a unit, through the region management. Information of attributes of these divided regions r is stored in the region management table.

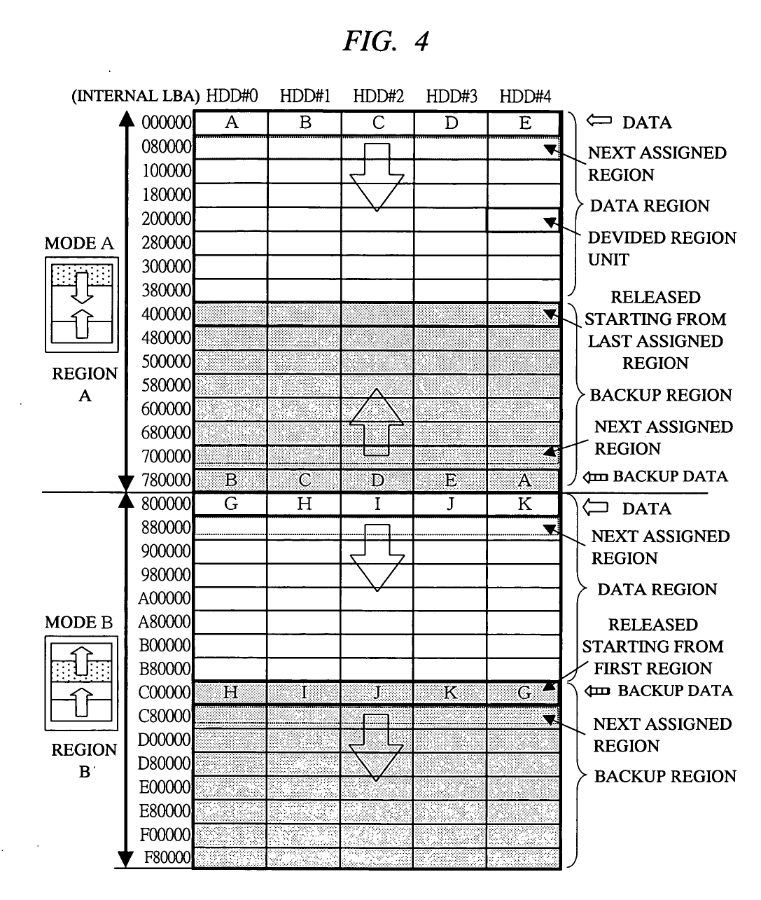

FIG. 4 is an explanatory diagram of a first backup mode (mode A) and a second backup mode (mode B). As an example, it shows a case where the first data and its backup data are stored in overall storage regions provided by five HDDs 30 of HDDs #0 to #4 which constitute a RAID group. The divided regions r are managed in accordance with internal LBAs in each of the HDDs 30. For example, in HDD #0, LBAs “000000H” to “07FFFFH” constitute one divided region r. Further, in HDD #0, 32 divided regions r having the same size provide a storage region that corresponds to the mode A and the mode B.

In the first backup mode, the storage regions of the HDD 30 are used sequentially from the top region to store usual first data and used as a backup region sequentially from the last region. In this mode, the old backup data are left preferentially. If there are no free space regions available or a remaining capacity is reduced to a predetermined level, the backup regions are sequentially used from the latest ones to overwrite the first data in them.

In the mode A shown in an upper part of FIG. 4, in an overall storage region that corresponds to the mode A, that is, a storage region (referred to as region A) composed of 80 (16×5) divided regions r, 50% of the regions from the top region is used as a data region to store the usual first data and the remaining 50% of the regions is used as a backup region to store the backup data. The data region may be used as a user data region dedicated to store the user data especially from the host information processor 300. An icon shown to the left in the figure indicates the mode A. The controller 10 stores the first data in the data region from the top divided region r. For example, at first, the first data composed of the striping data A to E is stored in the top divided region r in each of the HDDs #0 to #4. A dotted-line frame shown below it indicates a region which will be allocated next as a data region. Further, besides storing the first data, the controller 10 stores the backup data by using the backup regions sequentially from the last divided region r toward the top one. For example, first, backup data (data B to E and data A) of the striping data A to E are stored into the last divided region r in the region A of each of HDDs #0 to #4 in the locations shifted from those of the first data. A dotted-line frame shown above it indicates a region which will be allocated next as a backup region. When storing the first data and the backup data, the controller 10 performs the LBA conversion to determine divided regions allocated as a data region and a backup region and stores the information about this allocation in the region management table. If a predetermined capacity of the data region is used up for the storage of the first data, the used backup regions are released and used sequentially from the divided regions r (one or more regions) allocated as the backup region most recently.

In the second backup mode, the storage regions of the HDD 30 are used sequentially from the top one of these regions to store the first data, while using the regions sequentially from, for example, an intermediate one as backup regions. This corresponds to the case where 50% of the regions are used as the backup regions. In this mode, the more recent backup data are left preferentially. If there are no free space regions any more, the older backup regions are sequentially released to overwrite the first data in them.

In the mode B shown at a lower part of the FIG. 4, in an overall storage region that corresponds to the mode B, that is, a storage region (referred to as region B) composed of 80 divided regions r, 50% of the regions from the top region is used as a data region to store the usual first data and the remaining 50% of the regions are used as a backup region to store the backup data. An icon shown to the left in the figure indicates the mode B. The controller 10 stores the first data in the data region from the top divided region r. For example, the first data composed of the striping data G to K is first stored in the top divided region r of the region B in each of the HDDs #0 to #4. A dotted-line frame shown below it indicates a region which will be allocated next as a data region. Further, besides storing the first data, the controller 10 stores the backup data by using the backup regions sequentially from the top divided region r toward the last one. For example, the backup data (data H to K and G) of the striping data G to K are stored into an intermediate location of the divided region r in region B of each of HDDs #0 to #4. A dotted-line frame shown above it indicates a region which will be allocated next as a backup region. If a predetermined capacity of the data region is used up to store the first data, the used backup regions are released and used sequentially from the divided regions r (one or more regions) allocated as the backup region least recently.

In the case of the mode A, the regions are released from the divided region r assigned as a backup region most recently. That is, the more recent backup data lose redundancy earlier to preserve redundancy of the less recent backup data. This method is suited for the case where data stored in the HDD 30 earlier as storage data is needed to be left, that is, the case where the data stored in an early period of use of the system is more important than the recent storage data. As this type of data, for example, the data of OS or an application program of the information processor 300 is installed in the region of the HDD 30 in the earliest period. For example, it is possible to hold the backup data of the OS data longer so as to prepare against a failure of the OS data.

In the case of the mode B, on the other hand, the regions are released from the divided region r assigned as a backup region least recently. That is, the less recent backup data lose redundancy earlier to preserve redundancy of the more recent backup data. This method is suited for the case where the more recent storage data is needed to be left, that is, data stored in a stable period/wearout period of use of the system is more important. By using and releasing the storage region as described in the cases of the modes, it is possible to adjust robustness of the data in accordance with the service situation and utilization aspect of the user.

<Write Process Flow>

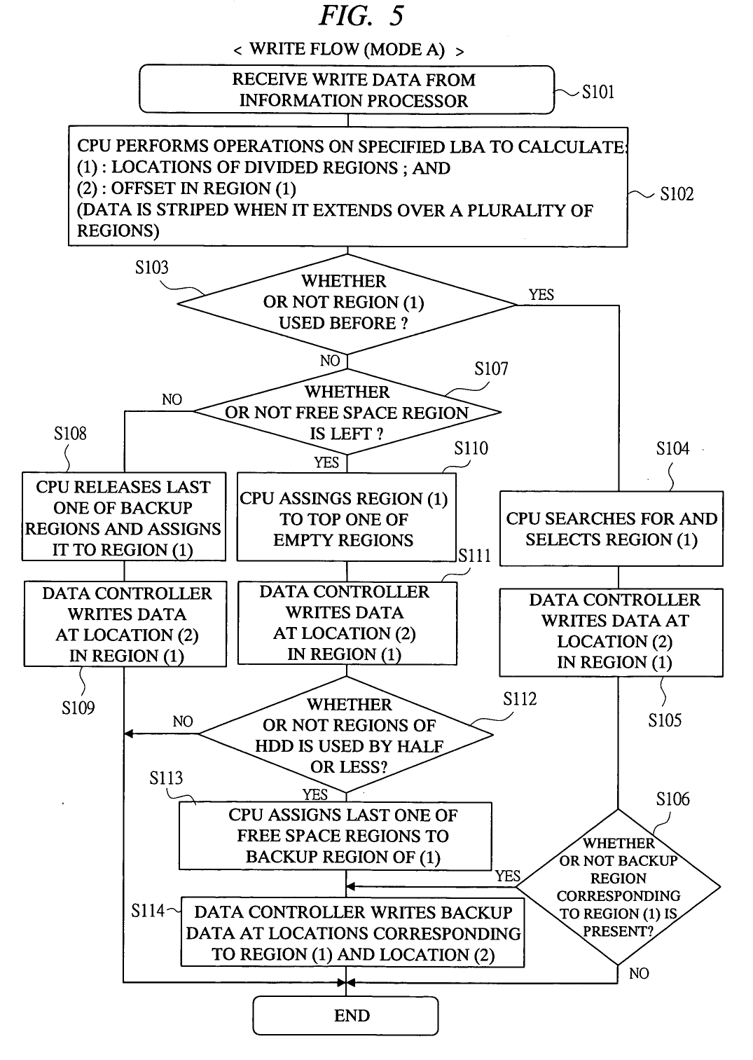

FIG. 5 is a flowchart for showing the process to write data to the HDD 30 in the disk array system 100 of the first embodiment. It shows especially the process employing the mode A.

The controller 10 receives write data from the information processor 300 (step S101). The CPU 11 of the controller 10 performs operations on an LBA specified by a received command to calculate a divided region location (hereinafter referred to as first location and the corresponding divided region r is referred to as first region) and an offset location in this first region, that is, a data storage location (hereinafter referred to as second location) (S102). Note that the controller 10 stripes the data to be stored if this data is stored over more than one divided regions r.

Next, it is determined whether the calculated first region has been used before by referencing a management variable which is used for the region management (S103). When it is determined that it has been used before (YES in S103), the CPU 11 searches for the first region and selects it (S104). Then, the data controller 14 writes data to a second location in the first region (S105). Thereafter, it is determined whether there is a backup region corresponding to the first region (S106) and when there is a backup region (YES), the process goes to S114, and otherwise (NO), the process ends.

When it is determined in the step S103 that the first region has not been used before (NO), the CPU 11 determines whether a free space region is left, in other words, whether there is an available divided region r by referencing the management variable (S107).

When it is determined in the step S107 that there is no free space region (NO), the CPU 11 releases the last one of the backup regions and assigns it as the first region (S108). The data controller 14 writes the data to the second location in the first region (S109), and the process ends.

When it is determined at the step S107 that there are free space regions (YES), the CPU 11 assigns the first region to the top one of the free space regions (S110). Then, the data controller 14 writes data to the second location in the first region (S111). Thereafter, it is determined whether the divided regions used for the storage of user data are less than half of the total, that is, whether there is a backup region (S112).

When it is determined in the step S112 that the data (first) regions are used more than half (NO), the process ends because backup is impossible. When the data regions are not used more than half (YES), since backup is possible, the CPU 11 assigns the last one of the free space regions as a backup region for the data in the first region (S113). Then, the data controller 14 writes backup data to a location that corresponds to the first region and the second location in the backup region (S114), and the process ends.

<Read Process Flow (Usual Case)>

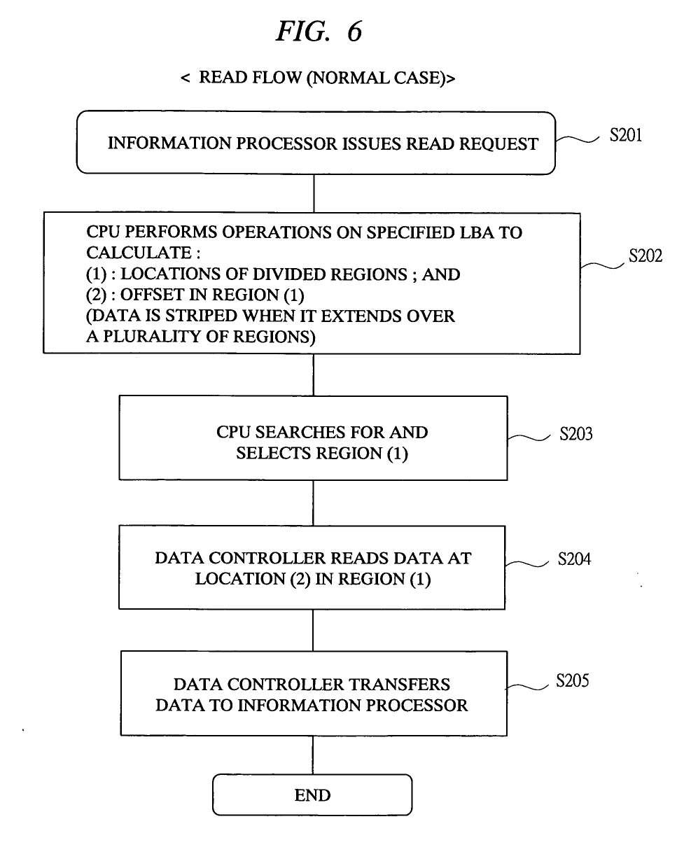

FIG. 6 is a flowchart for showing the process to read data from the HDD 30 in the disk array system 100 of the first embodiment. It shows especially normal process when the HDD 30 has no failure.

The controller 10 receives a read request from the information processor 300 (step S201). The CPU 11 performs operations on a specified LBA to calculate a first location (divided region location), a first region (divided region r), and a second location (offset location in the first region) (S202) corresponding to those in the write process described above. Note that the controller 10 stripes the data if this data is stored over more than one divided regions r.

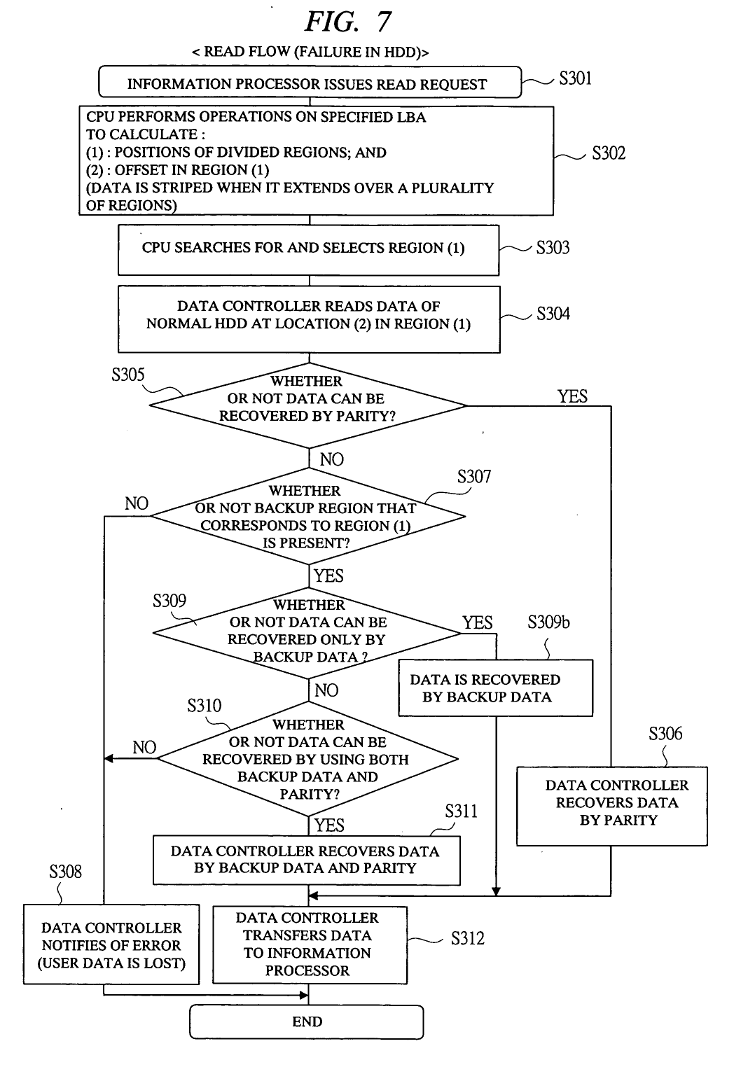

Next, the CPU 11 searches for the first region and selects it (S203). Then, the data controller 14 reads data from the second location in the first region (S204). Then, the data controller 14 transfers the read data to the information processor 300 (S205), and the process ends. <Read Process Flow (When HDD has failure)>FIG. 7 is a flowchart for showing the process to read data from the HDD 30 in the disk array system 100 of the first embodiment. It especially shows the process when the HDD 30 has a failure.

The controller 10 receives a read request from the information processor 300 (S301). The CPU 11 performs operations on a specified LBA to calculate a first location (divided region location), a first region (divided region r), and a second location (offset location in the first region) that correspond to those in the write process (S302). Note that the controller 10 stripes data if this data is stored over more than one divided regions r.

Next, the CPU 11 searches for the first region and selects it (S303). Then, the data controller 14 reads data from a normal HDD 30 at the second location in the first region (S304).

Subsequently, the controller 10 determines whether the data can be recovered from parity data (S305). When it is possible to recover the data in the determination (YES), the data controller 14 recovers the data by using the parity data (S306), and the process goes to step S312.

When it is determined in the step S305 that the data cannot be recovered (NO), the controller 10 determines whether there is a backup region that corresponds to the first region (S307). When there is no backup region (NO), the data controller 14 issues an error representing that “user data is lost” (S308), and the process ends.

When it is determined in the step S307 that there is a backup region (YES), the controller 10 determines whether the data can be recovered only by backup data (S309). When the data can be recovered only by backup data in the determination (YES), the backup data is read to recover the data by using the backup data (S309b) and the process goes to step S312. When the data cannot be recovered only by backup data (NO), the controller 10 determines whether the data can be recovered by using both the backup data and the parity data (S310). When it is determined that the data cannot be recovered even by using both of them (NO), the data controller 14 issues an error as described above (S308) and the process ends. When it is determined in the above-described step S310 that the data can be recovered by using both of them (YES), the data controller 14 recovers the data by using the backup data and the parity data (S311). Then, the data controller 14 transfers the read data to the information processor 300 (S312), and the process ends.

<Data Recovery in HDD Failure>

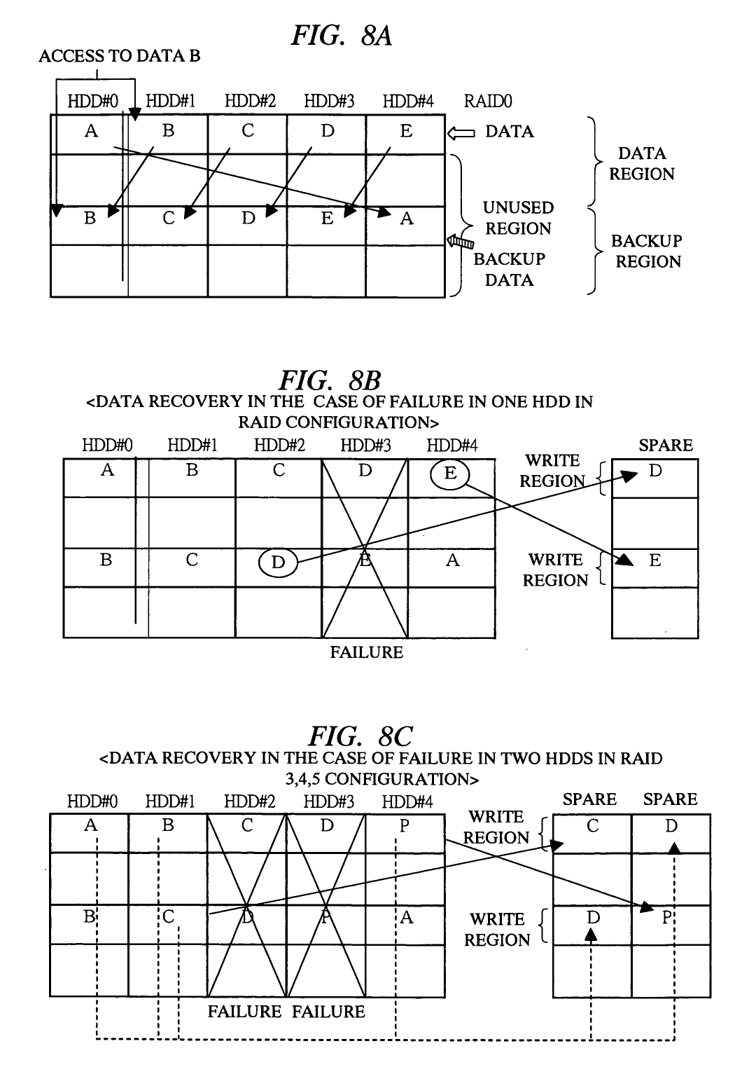

FIGS. 8A to 8C are explanatory diagrams of the process model for data recovery in the case of HDD failure (data read error) in a condition where first data and its backup data are stored according to the backup method. The FIG. 8A shows a state where the first data and the backup data are stored in a RAID configuration of RAID 0 system in which a RAID group is constituted of five HDDs 30 of HDDs #0 to #4. FIG. 8B shows data recovery corresponding to FIG. 8A in a case where a failure has occurred on one HDD in a RAID configuration. FIG. 8C shows data recovery in a case where a failure has occurred on two HDDs in a configuration of RAID 3, 4, or 5.

As shown in FIG. 8A, first data composed of striping data A to E is stored in a data region of storage regions of the RAID group, and backup data (data B to E and data A) of the first data is stored in a backup region of unused regions of the same RAID group with their storage destinations shifted to another HDD 30. When reading data, for example, when data B is read, two units of HDDs #1 and #0 can be utilized. In the case of the read operation by the method of RAID 4 or 5 in which accesses to first data (backup data) having a stripe size or smaller are concentrated on a particular disk, the backup data (first data) in another disk can be accessed to read the same data contents, and therefore, the effect of load distribution can be achieved.

It is supposed that an error has occurred in data read due to, for example, a failure on the HDD #3 when the controller 10 reads the first data composed of the striping data A to E in FIG. 8B. In this case, the controller 10 recovers the data D in HDD #3 by reading its backup data D in HDD #2. It is possible to recover the data only by copying it from the backup data. Further, when recovering the data stored in HDD #3 into a spare HDD or the like, for example, data D and E stored in this HDD #3 are recovered by reading backup data D from HDD #2 and the data E from HDD #4 and writing them to the storage locations of the spare HDD corresponding to those in the HDD #3.

In FIG. 8C, first data composed of striping data A to D and P (data A to D are non-parity data and data P is parity data) is stored in a data region in a RAID group composed of, for example, HDDs #0 to #4, and the backup data A to D and P are stored in a backup region in the same RAID group. It is supposed that an error has occurred in data reading due to a failure on, for example, HDDs #2 and #3 when the first data is acquired by reading the above-described striping data A to D and P. In this case, the controller 10 recovers data C in HDD #2 by reading backup data C in HDD #1 and recovers data D in HDD #3 by performing parity operations utilizing the data A and B, backup data C read from HDD #1, and data P read from HDD #4 because backup data D in HDD #2 is erroneous. Further, when recovering data stored in HDDs #2 and #3 into a spare HDD or the like, for example, when recovering data C, D and P stored in these HDDs #2 and #3, backup data C, data D recovered through the parity operations, and the data P are written to the locations in the spare HDD corresponding to storage locations in the HDDs #2 and #3 by using data A, B, and P read from HDDs #0, #1, and #4 respectively and backup data C.

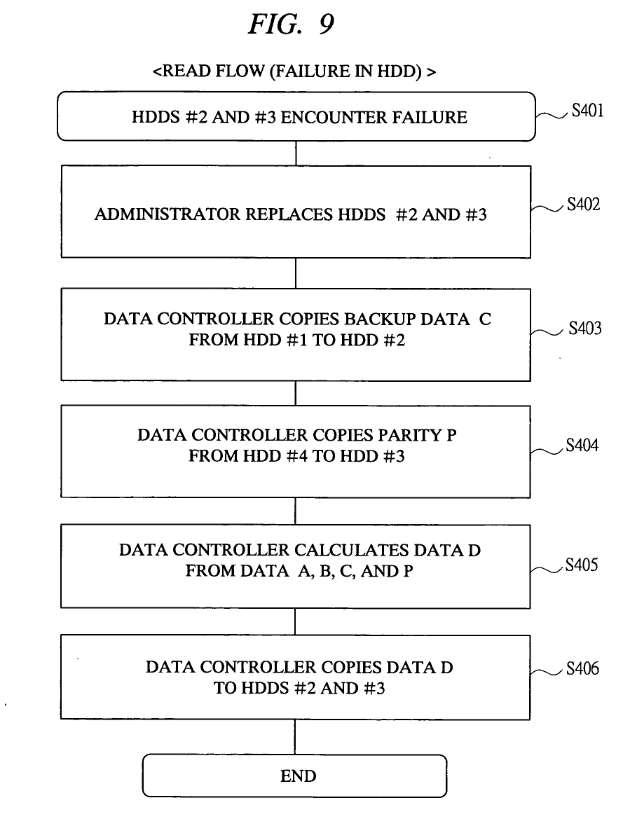

FIG. 9 is a flowchart for showing the process to perform data recovery from an error state corresponding to the case of FIG. 8C. First, in the disk array system 100, a failure is detected in, for example, HDDs #2 and #3 and issued or displayed (S401). After the failure is detected, an administrator of the disk array system 100 performs a job to replace the HDDs #2 and #3 with other HDDs 30 (S402). When the HDDs are recognized after the replacement, the data controller 14 in the controller 10 first copies backup data C from HDD #1 to the corresponding location (location of the data C) in the replaced HDD #2 (S403). Subsequently, the data controller 14 copies data P from HDD #4 to a corresponding location (location of the backup data P) in the replaced HDD #3 (S404). Subsequently, the data controller 14 obtains data D by the regenerations from data A, B, C, and P (S405). The data controller 14 copies the data D obtained by the calculation to the corresponding locations in the replaced HDDs #2 and #3 (S406), and the process ends.

In the case of FIG. 8C where it is assumed that data D is completely lost in the RAID group, data can be recovered only by using the backup data without using the parity data unless the usual first data and its backup data are both lost. Since it has redundancy equivalent to that of RAID 5+1, the user data is not lost even if about half a total number of the HDDs in the same RAID group encounter a failure. Therefore, it is possible to preserve redundancy that surpasses a typical failure rate in an early period even if no particular measures are taken. Similarly, the RAID 3 system also has redundancy equivalent to that of the RAID 3+1 system and is capable of obtaining data reliability equivalent to that of RAID 5+1.

<Setting Screen>

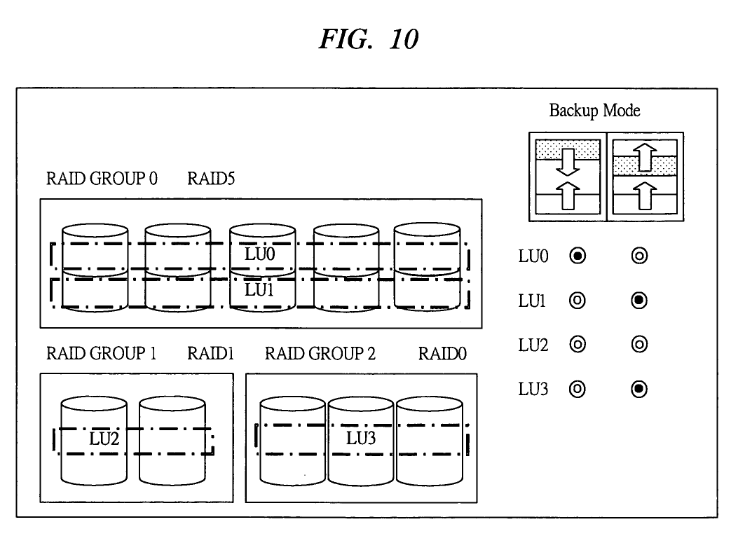

FIG. 10 shows a setting screen example and a setting example about the backup method of the first embodiment. A control device connected to the disk array system 100, for example, the information processor 300 in which a management program is installed is used to display the setting screen through the process of the management program, and the administrator or the like makes the settings.

In the setting screen example, RAID group 0 in accordance with RAID 5 composed of five HDDs 30 is set, and LU0 and LU1 are set as LUs in the RAID group 0. The logical unit numbers (LUs) are supposed to have numbers “0” and “1” respectively. Further, RAID 1 is set in RAID group 1, in which LU2 is set. Also, RAID 0 is set in RAID group 2, in which LU3 is set. As shown on the right side in the figure, the backup mode applied to each of the LUs is selected. In the upper part, icons that correspond to each backup mode (mode A and mode B) are indicated. The figure shows that, for example, the mode A is turned on in the LU0 and the mode B is turned on in the LU1 and LU3. Further, when selecting a mode other than the existing backup mode, a different detail setting screen relating to the backup process is used for setting. For example, a capacity of a backup region to be preserved for storage of backup data is set. Note that in the data for which mirroring control such as RAID 1 is set like in the case of LU2, the data reliability is preserved by mirroring. Therefore, it is not necessary in particular to use this backup system.

<Internal Operation Example>

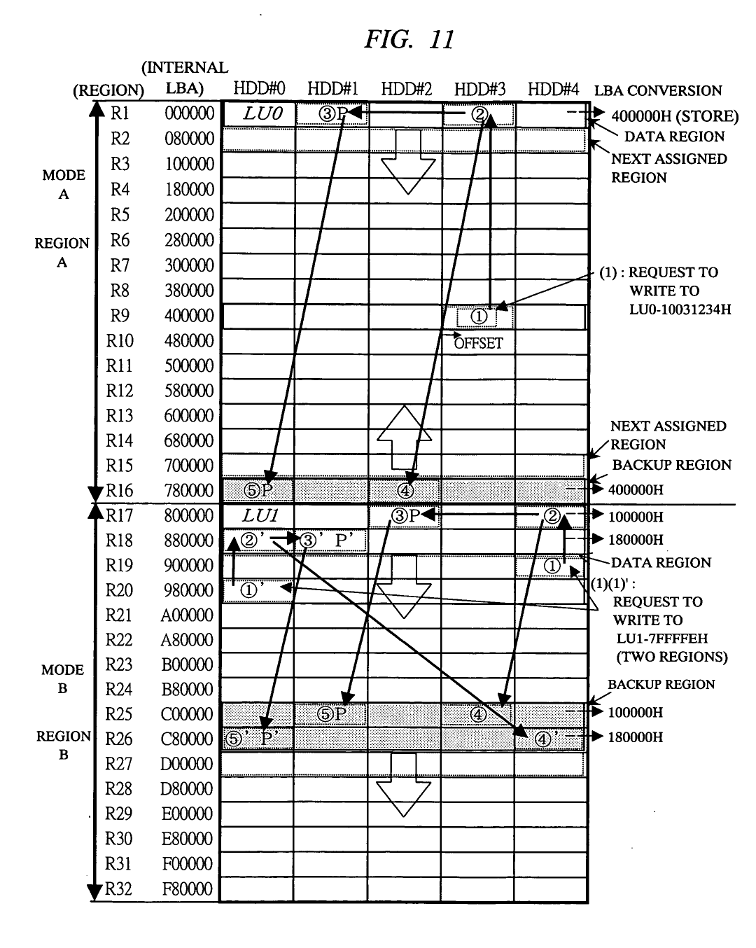

FIG. 11 shows an example of an internal operation that corresponds to the setting example in the disk array system 100. With respect to the LU0 and LU1 in RAID group 0 that accommodates the RAID 5, the backup process in mode A is performed in the LU0 and the backup process in mode B is performed the in LU1. In the HDDs #0 to #4 which constitute the RAID group 0, a storage region corresponding to internal LBAs “000000H” through “7FFFFFH” (hexadecimal) is set as a region A (R1 to R16) that accommodates the mode A and a storage region corresponding to LBAs “800000H” through “FFFFFFH” is set as a region B (R17 to R32). Note that the number of divisions in the storage region is small because it is just one example.

In order to perform efficient backup process, an overall storage region is handled in units of the divided region r. In FIG. 11, for example, a region from LBAs “000000H” through “07FFFFH” constitutes one divided region r. Further, a plurality of divided regions that extends over a plurality of HDDs 30 constitute one region (R) unit. For example, one region R is constituted of divided regions r that correspond to the same LBAs in HDDs #0 to #4. In the storage regions of the HDDs #0 to #4, regions R1 to R32 are formed. A region A composed of regions R1 to R16 and a region B composed of R17 to R32 each correspond to one LU (LU0 or LU1). Further, LBA conversion is utilized to manage the correlation between divided regions r and LBAs of original data storage destinations by using management variables in the region management table, and the consecutive free space regions are created and used in the overall storage region. For example, a top divided region r that corresponds to the LBA “000000H” in HDD #0 is managed by using address management variable r(0) and a region type management variable shown in FIG. 3. The controller 10 performs LBA conversion of data storage locations in accordance with the backup mode. For example, in the mode A, the controller 10 performs LBA conversion so that first data such as user data may be stored sequentially from top region R1 through last region R16 and the corresponding backup data may be stored sequentially from the last region R16 through the top region R1 in the region A. The controller 10 divides the region of each of LU0 and LU1 so as to correspond to the divided regions r of the HDD 30, and performs data read/write processes. In the case of the LU0 and LU1, a striping size and a size of each of the divided regions r in RAID 5 correspond to each other.

First, data write process of LU0 is shown in the upper part of FIG. 11. The process is performed in steps (1) through (5) in this order. In the mode A, locations are sequentially assigned as a backup region from the last location in the region A. The top region R1 is a data region in which data of LU0 is stored. The last region R16 in the region A is a backup region in which its backup data is stored. The region R2 is a data region assigned next to the region R1. The region R15 is a backup region assigned next to the region R16.

(1): For example, the information processor 300 issues a request for performing write operation to “10031234H” of LU0 by the logical addressing. The controller 10 calculate an internal address from the logical address. The logical address corresponds to a HDD's logical address (LBA), which is the write request for LBA “401234H” of HDD #3, that is, it is base address “400000H”+offset “1234H”.

(2): The controller 10 stores the LBA “400000H” of the base address in a management variable of the region management table through the LBA conversion. That is, it assigns the region R1 as a data region and stores an LBA value “400000H” in an address management variable that corresponds to the top divided region r of the HDD #3. Then, the controller 10 writes the write data to the same offset position (LBA“001234H”) of the same HDD (HDD #3) in the region R1 which provides a data region.

(3): The controller 10 generates parity data P of the data stored in the HDD #3, and similarly, writes the parity data P to the corresponding location in a parity storage destination HDD 30 in the region R, in this case, to the LBA “001234H” of HDD #1. By doing so, the data of LU0 is written as the first data in the data region.

(4): The controller 10 stores LBA “400000H” of the base address to the last region R16 which provides a backup region through the LBA conversion. That is, it assigns the region R16 as a backup region, and stores the LBA value “400000H” in an address management variable that corresponds to the last divided region r in the HDD #2. Then, the controller 10 stores backup data of the first data to the same offset location (LBA “781234H”) in another HDD 30 adjacent to the HDD #3 to which the first data is stored, in this case, HDD #2 in the region R16.

(5): Further, in the region R16, the controller 10 similarly stores the backup data P of the parity data P to the same offset location (LBA “781234H”) in an adjacent HDD 30, in this case, HDD #0 so as to correspond to the HDD #1 to which parity data P is stored.

Further, the lower part of FIG. 11 indicates data write process on LU1. The process is performed in steps (1) through (5) in this order. It especially indicates the case where a write region extends over two regions R. In the mode B, regions are sequentially assigned from a location of 50% as a backup region in the region B. The regions R17 and R18 provide a data region in which data of LU1 is stored. The regions R25 and R26 placed at the location of 50% provide a backup region in which its backup data is stored. The region R19 provides a data region assigned next to the regions R17 and R18. The region R27 provides a backup region assigned next to the regions 25 and 26.

(1): For example, the information processor 300 issues a request for performing write operation to “7FFFFEH” of LU1 by the logical addressing. In this write request, a write region extends over two regions R19 and R20. The write operation is performed to a divided region r of the HDD #4 in the region R19 and a divided region r of the HDD #0 in the region R20. The base addresses in the region B that correspond to these divided regions r are obtained as “100000H” and “180000H” respectively.

(2): Through the LBA conversion, the controller 10 assigns management variables (“100000H” and “180000H” in FIG. 11) in the region management table to the two write regions R, that is, R17 and R18 which provide top data regions in region B, and writes data to the relevant locations in the divided regions r, which provide a first-data storage destination in each of the regions R.

(3): The controller 10 generates parity data P and P′ of the data stored in the two divided regions r and writes them to the corresponding locations in the regions R17 and R18 in parity storage destination HDDs 30, that is, HDDs #2 and #1 in this case.

(4): Through LBA conversion, the controller 10 assigns the regions from a position of 50% as backup region in the region B (“100000H” and “180000H” in FIG. 11) and writes backup data of the data stored in the R17 and R18 to the corresponding locations in the regions R25 and R26 which provide a backup region in adjacent other HDDs 30, that is, HDDs #3 and #4 in this case.

(5): Similarly, the controller 10 stores backup data P and P′ of the parity data P and P′ to the corresponding locations in adjacent other HDDs 30, that is, HDDs #1 and #0 in this case.

<Effect and Data Reliability>

As described above, according to the first embodiment, it is possible to avoid the data loss by performing the backup process. In an operation of the disk array system, generally in the early failure period, a HDD has a high failure rate but a lot of margin in its free capacity. Therefore, by applying the backup method of this embodiment, it is possible to secure the redundancy/data reliability especially in the early failure period in which the HDD failure rate is high.

This backup method can be applied to any RAID system of RAID 3, 4, 5, or 0. Even in the case of the RAID 0, the reliability equivalent to that of RAID 0+1 can be secured if a used capacity of the storage region of the device is small. Further, owing to the region management, since it is possible to recover the data by copying only a data section used to store first data and backup data, the data recovery time can be reduced. Also in the case of RAID 3, 4, or 5, in the case where the failure occurs only in one disk, data can be recovered without recalculating parity data. Further, even if two disks encounter a failure, data can be recovered by utilizing error code correction (ECC). Even in the case of a HDD double failure in which an early failure rate of the HDD surpasses redundancy of the device, the user data can be protected and the system robustness can be improved by employing this backup method.

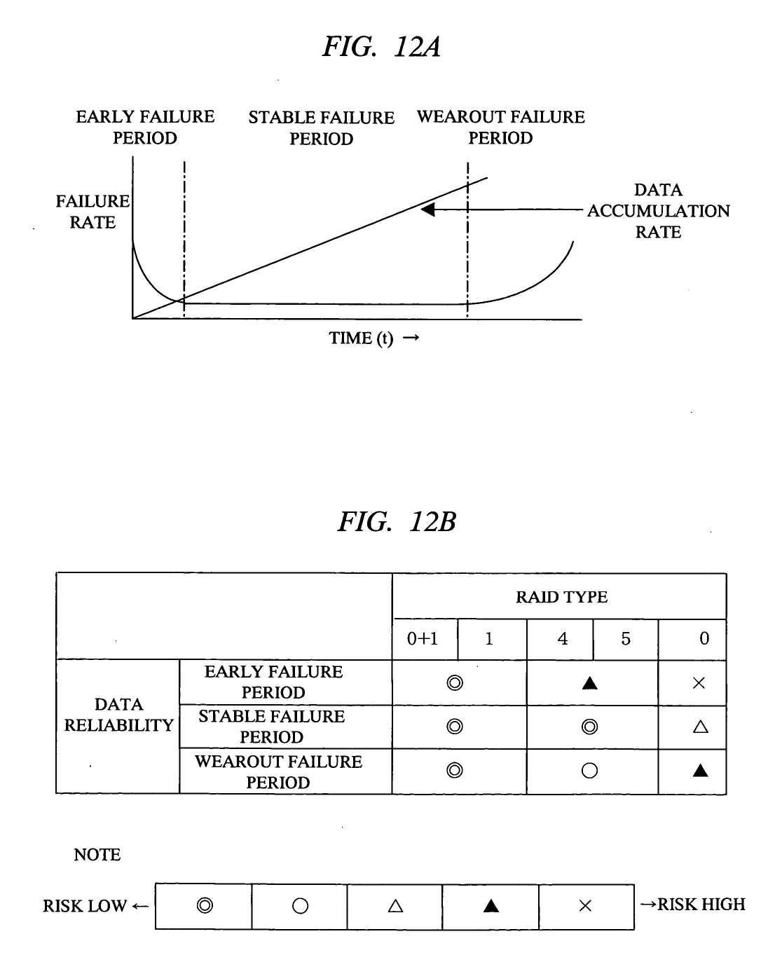

The effects (data reliability) of the first embodiment will be described below from the viewpoint of a device failure rate, a data accumulation rate, and a RAID system. FIG. 12A is a graph for showing a relationship between an empirical population failure rate curve and a data accumulation rate (capacity usage rate) in a disk array system. FIG. 12B is a table for showing data reliability in accordance with a RAID system and a device operation period.

First, typical forms employed by the user for utilizing a disk array system are roughly classified from the viewpoint of data reliability as follows. The data reliability is high in RAID 0+1 and RAID 1, medium in RAID 4 and RAID 5, and low in RAID 0. A cost of data capacity (cost performance) is high (CP=low) in RAID 0+1 and RAID 1, medium (medium) in RAID 4 and RAID 5, and low (high) in RAID 0.

And, supposing a failure rate of the hard disk to be constant, the more HDDs are included in the same RAID group, the higher an occurrence risk of a HDD failure and data loss becomes. As described above, normally, the cost performance of the data capacity and the data reliability are always in a trade off relationship.

Further, the device failure rate tends to follow a bathtub curve (failure rate curve) as shown in FIG. 12A, and the failures that have occurred in a specific period are typically classified into three group; early failure period, stable failure period, and wearout failure period, which have the following characteristics. During use of the device, early period failures, stable failures, and wearout failures occur in an early failure period, a stable period, and a wearout failure period respectively. The failure rate is high in the early failure period, stabilized in the stable period, and increases in the wearout failure period.

The early period failures are caused by a lot failure, a common-cause failures by error of designing, or the like and occur so often. To avoid or prevent them, it is necessary to secure redundancy in the device by using predetermined means and perform long-term inspection by the manufacturer. This redundancy can be secured by controlling data storage by the use of various RAID systems such as RAID 0+1, 1, 3, 4, and 5 typically in the case of a disk array system.

The stable failures are caused by a lifetime-related random factor such as a sudden failure of a component and occur relatively rarely. To avoid or prevent them, it is necessary to secure the redundancy on the side of the device and perform check/prevention maintenance on the side of manufacturer.

The wearout failures are caused by wearout or deterioration and occur increasingly as time passes by. To avoid or prevent them, it is necessary to predict a failure on the side of the device and perform predictive maintenance/replacement of the device on the side of manufacturer. By predicting failures as described above, if error of a device occurs increasingly, the device is decided not to have a long lifetime any more and replaced.

In FIG. 12A, a failure rate of the HDD 30 also corresponds to a failure rate curve. A data accumulation rate corresponds to an accumulation rate (capacity usage rate) of data stored in a storage region provided by the HDD 30 in the disk array system 100. Generally, the data accumulation rate increases as time passes by.

In FIG. 12B, it cannot be said by any means that a data loss risk in the early failure period of an operation of the disk array system is low even in the case of RAID 4 and 5. For example, if two HDDs encounter a failure in a RAID group, data loss occurs. In the table of FIG. 12B showing the data reliability, in the case of RAID 4 or 5, the risk (data loss risk) is comparatively high in an early failure period, low in a stable period, and comparatively low in a wearout failure period. In the case of RAID 0+1 or 1, the risk is low in every period. In the case of RAID 0, the risk is considerably high in the early failure period, medium in the stable period, and comparatively high in the wearout failure period.

It can be said that an occurrence rate of early period failures in the disk array system is high in a period when a data accumulation rate in the HDD is 50% or less. By using a backup method of the embodiments of the present invention, it is possible to cover (accommodate) an early failure period when the failure rate is high until the data accumulation rate exceeds about 50%. Therefore, even if the user employs the RAID 0 system with low reliability, since the backup data of the first data is saved in a free space region of the disk (HDD 30), the data can be recovered and a subsequent shift to the stable period can be facilitated. A merit that data reliability in an early failure period of an operation of the system can be secured is large.

### Second Embodiment

Next, a disk array system of the second embodiment of the present invention will be described. According to a backup method of the second embodiment, the process is performed, in which first data and the backup data are stored in a paired volumes, for example, a certain storage volume such as an LU and another storage volume such as another LU so that the storage locations thereof are crossed to each other (hereinafter referred to as cross process) in an overall storage region provided by a plurality of HDDs 30. In other words, the process to arrange a data region and a backup region so that they may cross each other in this pair is performed. Volumes that store the data with different properties, especially, the data with different size are used as the storage volumes to be paired. Hardware configuration or the like is the same as that of the first embodiment.

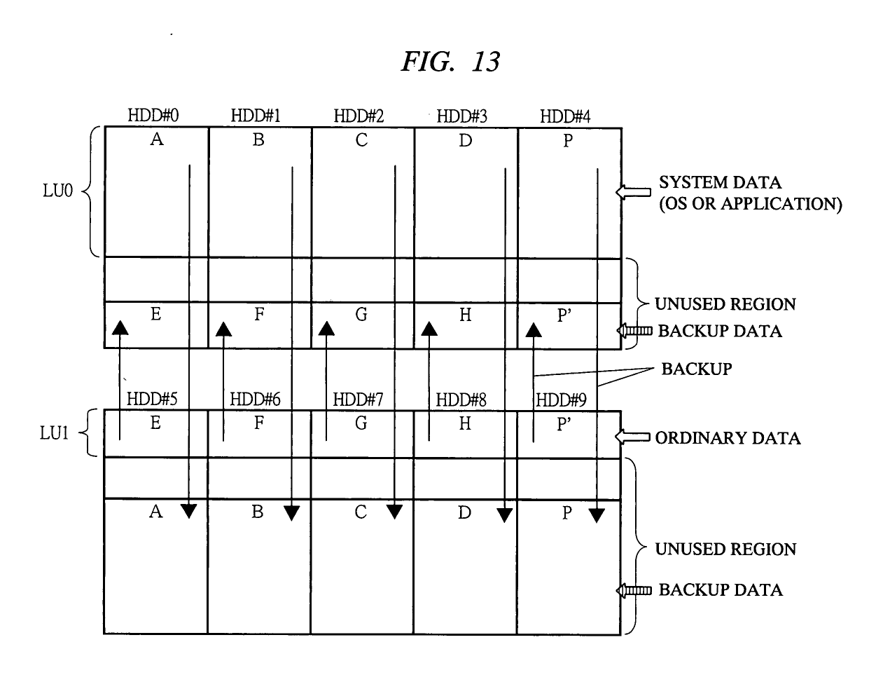

FIG. 13 is an explanatory diagram showing an outline of the backup method of the second embodiment. For example, there is an overall storage region provided by 10 HDDs 30 of HDDs #0 to #9. In a storage region provided by the HDDs #0 to #4, LU0 which serving as one storage volume is set in a data region. Meanwhile, in a storage region provided by the HDDs #5 to #9, LU1 serving as the other storage volume is set in the data region. The LU0 is a region for storing system data such as the data for constituting the OS and an application of the information processor 300. The LU1 is a region for storing ordinary data such as user data from the information processor 300.

A controller 10 sets these LU0 and LU1 that store data with different properties as the pair of LUs. The controller 10 stores backup data of data A to D and P stored in LU0 into an unused region of a HDD group of the pair partner LU1 and also stores backup data of data E to H and P′ stored in LU1 into an unused region of a HDD group of the pair partner LU0. In this manner, the controller 10 conducts control so that the storage locations of the first data and its backup data are crossed to each other in the paired regions and HDDs 30.

For example, the comparison between LU0 for storing the OS and an application and LU1 for storing general-purpose data which are used as the storage regions preserved in the HDDs 30 may reveal that a large capacity is used from an early stage of device usage in the LU0 while the capacity of the LU1 is gradually increased along with the data accumulation. Therefore, even if the first data occupies 50% or more of the overall storage region in the HDD 30, its backup data can be held as far as the first data does not occupy so much of a capacity of the pair partner LU.

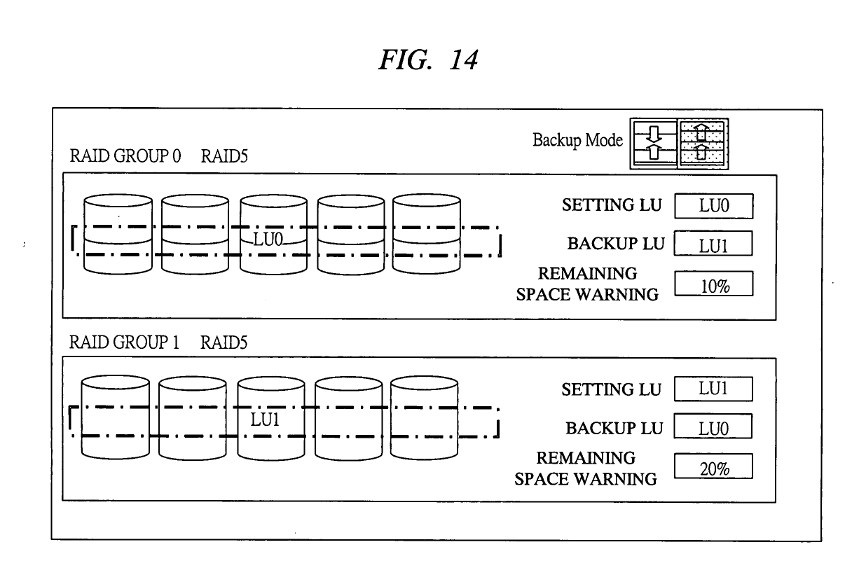

FIG. 14 shows an example of the setting screen in a case where the cross process is performed. The setting process for the cross process is performed in a device such as a management device provided with a program for utilizing and managing the disk array system 100. For example, a management program in the information processor 300 connected as a management server to the disk array system 100 is used to display the setting screen through a user interface such as a Web page by communicating with the disk array system 100, and a administrator may input the settings. The set information is transmitted to the disk array system 100 and held in a memory, and then, the controller 10 operates according to the settings.

The example of the setting screen shows a state where RAID groups 0 and 1 are set in accordance with a RAID 5 system. Further, by selecting an icon relating to a backup mode, the first backup mode (mode A) is selected. Further, the LU0 and LU1 are set in the RAID groups 0 and 1, respectively. In the RAID group 0, the LU0 is set as a set LU, that is, an LU to which the process in accordance with this backup method is to be performed and in which the first data is to be stored. Also, the LU1 is set as a backup LU, that is, a pair partner LU in which the backup data of the data of this set LU is to be stored. Similarly, in the RAID group 1, the LU1 and LU0 are set as the set LU and the backup LU, respectively. By setting the LU0 and LU1 as a pair as described above, it becomes possible to realize the process to store the first data and the backup data in free space regions of the paired LUs so that they may cross each other. Further, as shown in the setting screen, it is also preferable to show a remaining amount (%) available for the data storage to the storage region of the HDDs 30 of the RAID group to notify it for the administrator or the user as a warning. A remaining space (capacity) can be acquired by, for example, the region management. By referencing the region management table, a remaining space can be obtained through simple calculations. By displaying the remaining space warning, the administrator or the user is recommended to, for example, backup data by utilizing other backup means such as a magnetic tape device.

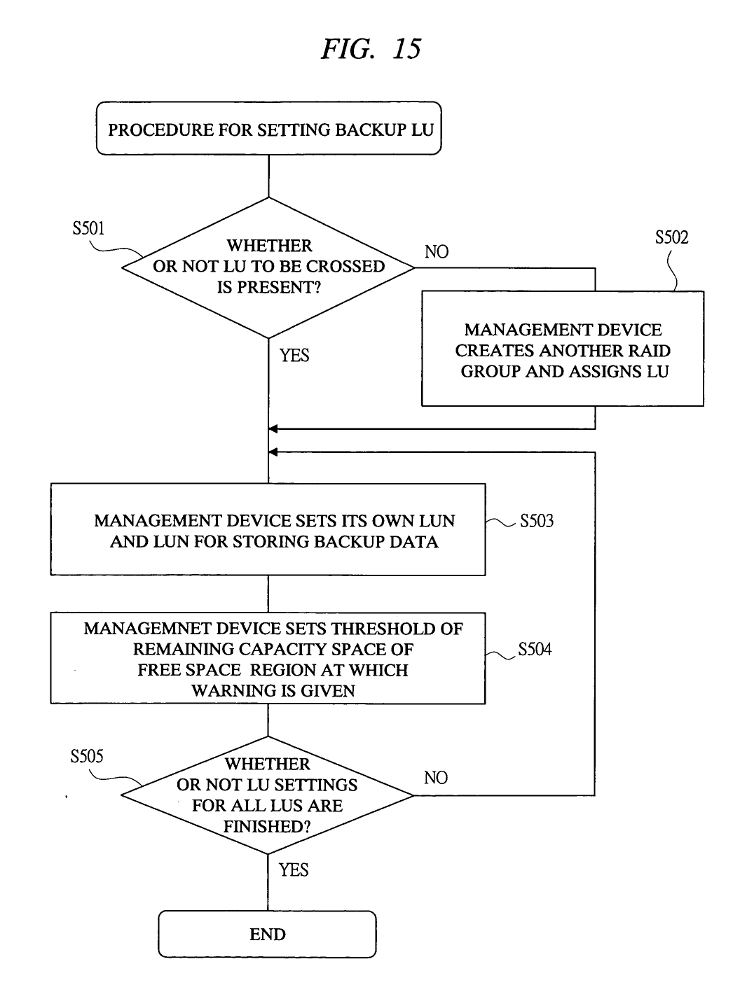

FIG. 15 is a flowchart for showing a setting procedure for the cross process, especially a backup LU setting procedure.

The controller 10 determines whether there is an LU to be crossed with a certain LU, for example, the LUG by acquiring or checking a capacity of an overall storage region of the HDDs 30 that is occupied by data (S501). When it is determined that there is no LU to be crossed (NO), the management device creates and sets another RAID group and assigns an LU to be crossed in the created RAID (S502).

Next, the management device sets a logical unit number (LUN) of the set LU itself for storing the first data and an LUN of its pair partner backup LU for storing the backup data (S503). For example, they are set to “0” and “1” respectively. Further, the management device sets a threshold of the remaining capacity space of free space regions in the HDD 30 at which the remaining space warning is given, that is, a trigger for performing backup process of data to a magnetic tape device or the like. (S504). After these settings are completed for all of the LUs (S505), the setting ends.

According to the backup method of the second embodiment, it is possible to efficiently store the backup data by selecting the pair of LUs.

<Load Distribution of HDD Access>

By applying the backup method of the first or second embodiment to RAID 4 or 5, it is possible to avoid the access being concentrated on a specific HDD 30. The access concentration on a HDD includes such types as a first type in which data each having a stripe size or smaller is accessed to one HDD and a second type in which data over at least two adjacent HDDs is accessed. Loads due to access concentration cannot be solved by a conventional method in any of these types.

In an example of the first type, it is assumed that first data composed of data A to E is stored in a data region and backup data B to E and A of this first data is stored in a backup region by automatic backup process in HDDs #0 to #4 which constitute a RAID group that accommodates, for example, RAID 4 or 5. Each of the data and its backup data are stored at the corresponding locations in different HDDs 30. For example, in the case where the data C in HDD #2 is accessed, by employing a method in which data C and its backup data C in HDD #1 are alternately accessed (alternating access method), the HDD access loads can be distributed and accesses concentration on the specific HDD #2 can be avoided, and consequently, it is possible to reduce the waiting time for performing a seeking operation (data read operation) to the HDD 30. This load distribution is effective mainly to read data.

In an example of the second type, it is assumed that the same data storage state is provided in a RAID group composed of, for example, the HDDs #0 to #4. When considering the case where data C and D over two adjacent HDDs #2 and #3 are accessed, the alternating access method can be employed to reduce the waiting time by distributing the loads of accessing data C over HDDs #1 and #2. However, since the HDD #2 is accessed for both data C (user data) and data D (backup data), an effect of load distribution cannot be obtained over the whole region (HDDs #1 to #3). In order to improve the load distribution effect in this type, in relation to the alternating access of the above-described example, a frequency at which HDD #1 (backup data C) and HDD #3 (user data D) are accessed is set higher than that at which HDD #2 (user data C and back up data D) is accessed. By doing so, more efficient load distribution can be realized over the whole region (HDDs #1 to #3).

As described above, by using the method of alternately accessing the first data and its backup data in data access from the controller 10 to a plurality of HDDs 30, the load distribution effect can be obtained in accordance with each of the access concentration types. In the method of the second embodiment in which the first data and its backup data in a pair of LUs are crossed in arrangement, data is not duplicated in the same disk, and therefore, more efficient load distribution is possible. If there is no cross arrangement, a large effect can be obtained especially for the first type. If there is a cross arrangement, a large effect can be obtained in both of the first and second types.

### Third Embodiment

Next, a disk array system of the third embodiment of the present invention will be described. In a backup method of the third embodiment, a region for storing important data (referred to as important data region) in accordance with an importance level is provided in an overall storage region provided by a plurality of HDDs 30, and the first data to be stored in the HDD 30 is allocated to a region in accordance to is importance level. Also, the data of this first data to be stored in the important data region is automatically backed up as in the case of the first embodiment or the like. The controller 10 backs up only the data in, for example, the important data region. The hardware configuration or the like is the same as that of the first embodiment.

In comparison to a mainframe-computer system for performing the block access in which stable access unit for data is an LBA, a system such as a network attached storage (NAS) for performing the data access by a path/file name unit (file access) has a large degree of freedom of a design such as an internal data layout and a data write location in a storage region of a disk array system. Therefore, it is possible to operate the backup process in accordance with the backup method in the first embodiment or the like as a part of the system permanently and automatically. The third embodiment shows an example thereof.

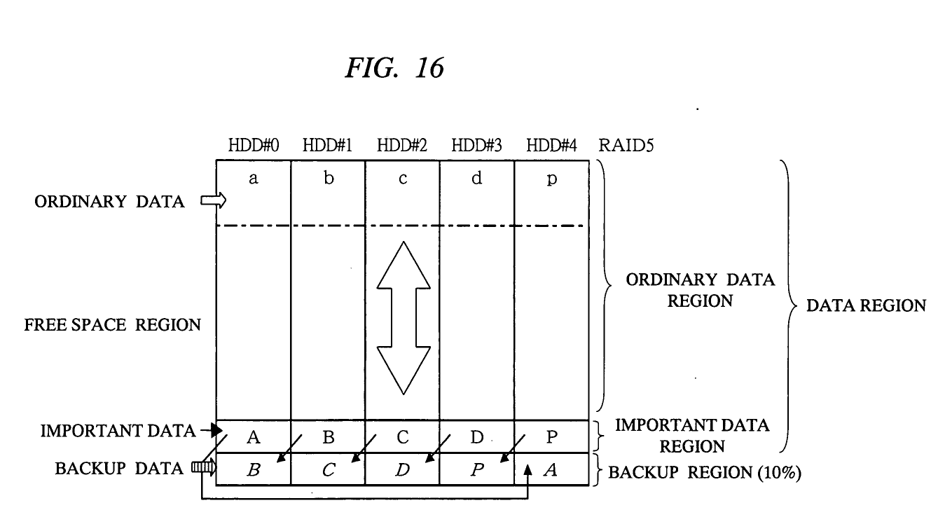

FIG. 16 is an explanatory diagram of an outline of the backup method in the third embodiment. For example, an overall storage region composed of five HDDs 30, that is, HDDs #0 to #4 which constitute a RAID group in accordance with RAID 5 is provided. In the overall storage region, a data region and a backup region are provided. The data region is used to store first data such as the user data. The backup region is used to store the backup data. In this embodiment, an important data region preserved inside the system is provided in the data region and the data determined to be more important in the first data is stored in the important data region. By a write operation performed from the controller 10, ordinary data a to d and p are stored in a data region, for example, in a top data region. A free space region is a region which is not used yet to store the first data.

For example, in a disk array system 100 for conducting the control compatible with an NAS and in accordance with the RAID 5 system (NAS system), a part of a system capacity of the HDD 30, for example, 10% of an overall storage region is preserved as a backup region for storing backup data by using this backup method. A size to be set for this purpose can be varied according to need. Further, the important data region in the data region that corresponds to the backup region is set inside the system. By the control conducted by the controller 10, the data expected to be important in the data stored in the data region is allocated to the important data region. In this manner, this important data is protected from being lost.

The controller 10 allocates an important data in the storage data to the HDD 30 into the important data region and automatically backs up the storage data to the important data region into the backup region. Then, it moves the storage data in the important data region into an ordinary data region according to need. For example, the backup data A to D and P of the data A to D and P in the important data region is stored into the backup region with shifting the storage destination HDDs. For example, the data as follows is allocated into the important data region.

(1): The data which is not read for a certain time after being written is held in the important data region. As a rule, the controller 10 once allocates all write data to the storage region of the HDD 30 into this important data region. However, if the data size is extremely small, it is preferable to directly write the data into the ordinary data region in the data region. This is because the importance of this data is supposed small, even if this data is lost. After the controller 10 has once stored the data into the important data region, the controller 10 moves this stored data into the ordinary data region in the data region at a next trigger. First, when the data is not accessed from a host for a certain time after being written into the important data region, the data is moved. Second, when the data is read after being written into the important data region, this data is moved. The second trigger is assumed to be the case of reading data after once being written or the case of backing up data to a magnetic tape device or the like by the controller 10. In this case, after writing the data into the important data region, when the controller 10 reads this data from the important data region in a read operation of this data, it moves the data to the ordinary data region and releases the occupied area by this data in the backup data region.

(2): The data frequently accessed in a read operation is held in the important data region. The controller 10 allocates the data having a large number of read accesses or a high read access frequency among the write data to the storage region of the HDD 30 into the important data region. The references for this allocation includes a specified number of accesses, a specified access frequency, their orders from the top, and the like. The data and file having such properties may include, for example, a database file (table), a Web file which constitutes a Web page, and the like. Further, it is preferable to apply the following restriction to the data be processed. According to the applied restriction, in relation to the count of the number of accesses, a counted value is carried over for a certain period even if the same data or file is updated. Also, if there are no accesses for a certain time after that, the counted value is cleared and the data is moved to the ordinary data region.

According to the backup method of the third embodiment, even if up to two HDDs 30 encounter a failure (in the case of RAID 5), data in the important data region is not lost, and moreover, it is possible to continuously read and access to the important data region even in the case of the restoration using the data backed up by a volume system (later-described backup means), more specifically, the backup region is capable of being accessed even during the restoration, and the most recent data can be automatically restored.

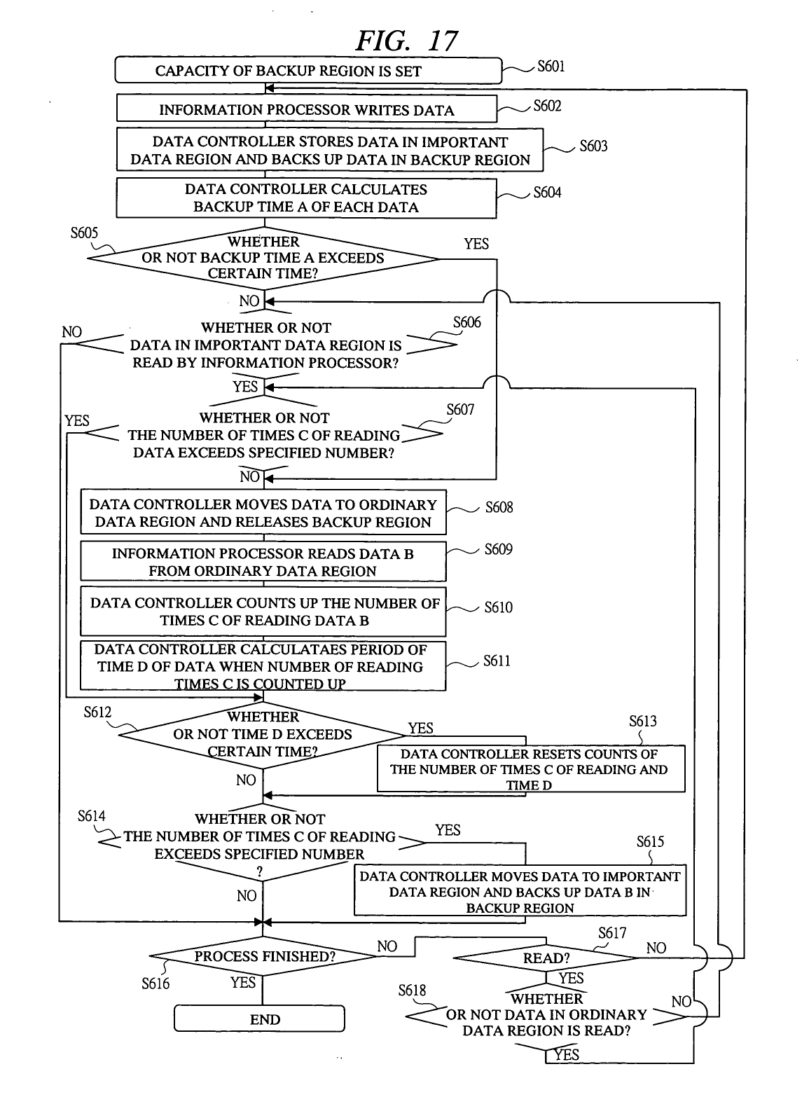

FIG. 17 shows a flowchart of the backup method of the third embodiment. A management device or the like sets a capacity of the backup region (S601). An administrator sets a capacity of the backup region to, for example, 10% of an overall capacity. After setting the capacity, the information processor 300 performs a data write operation to the disk array system 100 (S602). For example, it issues a command for writing the data B as first data and the write data, and in response to the received command and the write data, the controller 10 writes the data B into the important data region in the data region.

The data controller 14 backs up the data (data B) in the important data region into the backup region (S603). That is, the backup data (data B) is stored in the backup region of another HDD 30. The data controller 14 calculates and recognizes a backup time A for each of the data (S604). The data controller 14 determines whether the backup time A for the data (data B) exceeds a certain time (S605). When the backup time exceeds a certain time (YES), the process goes to S608. When it does not exceed a certain time (NO), it is subsequently determined whether a read operation (read request) of the backup data (data B) is given from the information processor 300 (S606). When no read request is given (NO), the process moves to step S616. When the read request is given (YES), it is subsequently determined whether the number of times C of reading the data (data B) exceeds a specified number (S607). The data controller 14 counts the number of times C of the reading when the data is read. When the number exceeds the specified number (YES), the process moves to S612. When it does not exceed the specified number (NO), the data controller 14 subsequently moves the data (data B) in the important data region into the ordinary data region in the data region (S608). Along with this, it releases the backup region used to store this data. In response to the read request, the data B in the ordinary data region is read by the information processor 300 (S609). The data controller 14 counts up the number of times C of reading the data (data B) when it is read (S610). The data controller 14 calculates a period of time D of the data when the number of reading times C is counted up (S611). Then, it is determined whether this period of time D exceeds a certain period of time (S612). When it exceeds a certain period of time (YES), the data controller 14 resets the counts of the number of reading times C and period of time D (S613). Subsequently, it is determined whether the number of reading times C exceeds a specified number (S614), and then it exceeds a specified number (YES), the data controller 14 moves the data into the important data region, and along with it, backs up the data (data B) into the backup region (S615).

After that, it is determined whether the process is finished (S616), and when there is no request any more from the information processor 300, the process ends. When it is not the end of the process, that is, there is a request from the information processor 300, it is determined whether the request is a read request (S617), and when it is a write request (NO), the process returns to the data write process in S602. When it is a read request (YES), it is determined whether data in the ordinary data region is to be read (S618), and when the data in the ordinary data region is to be read (YES), the process returns to S607. When the data in the ordinary data region is not to be read (NO), the process returns to S606.

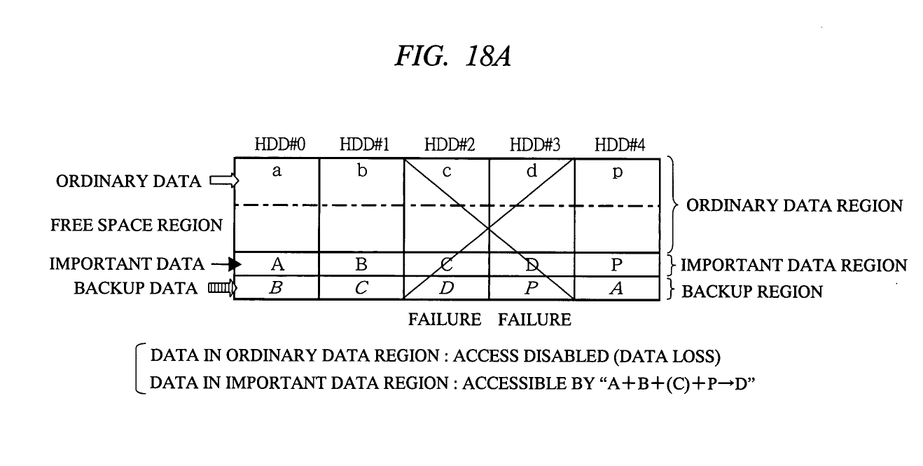

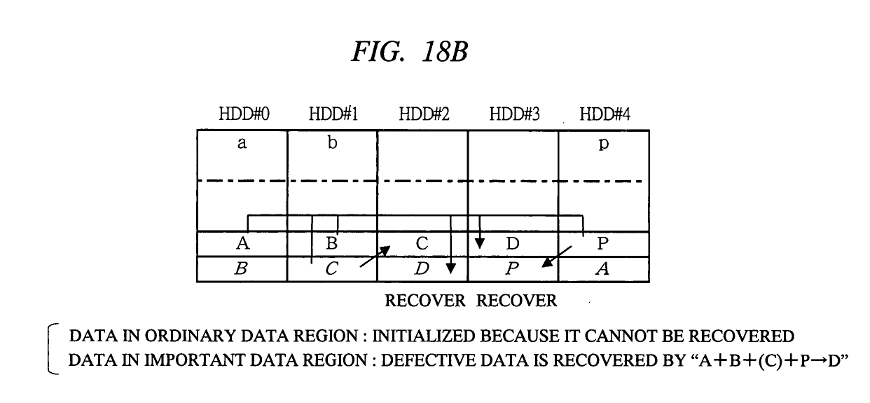

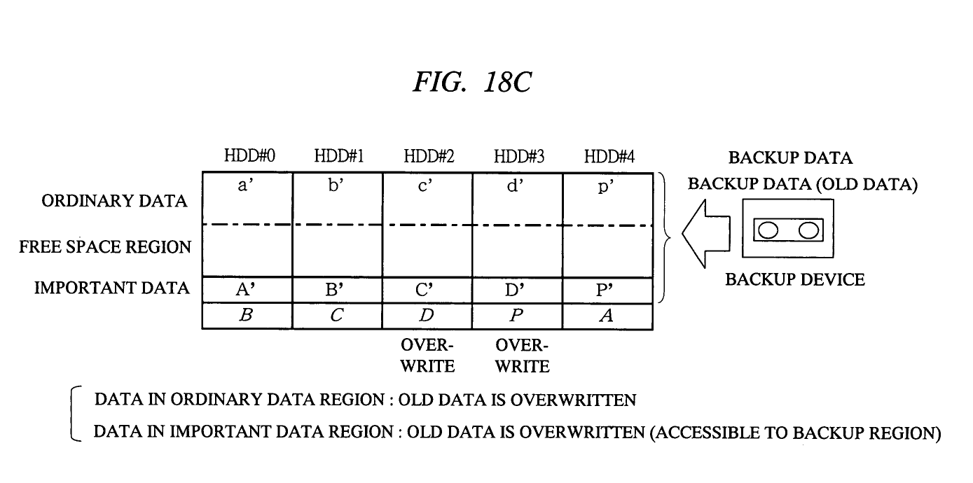

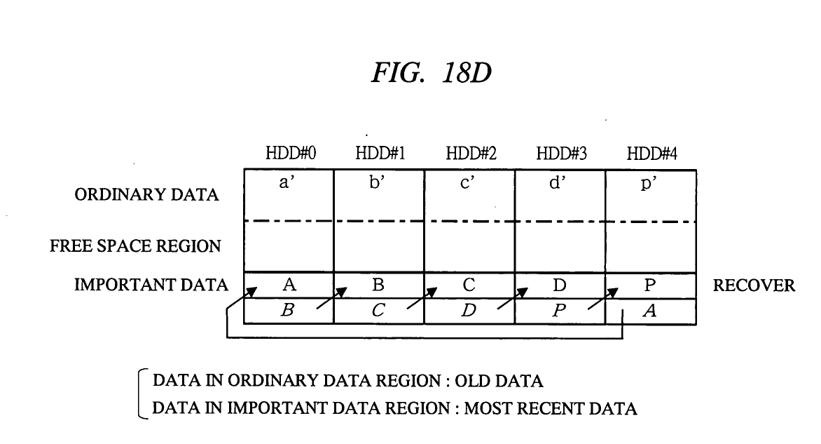

FIGS. 18A to 18D show a data recovery procedure and a concept of internal process in the case where a HDD double failure has occurred, that is, two HDDs have encountered a failure according to the third embodiment.

FIG. 18A shows a state where a HDD double failure has occurred. For example, in the data region of the storage region in a RAID group composed of five HDDs 30, that is, HDDs #0 to #4, the ordinary data region stores ordinary data composed of data a to d and p and the important data region stores important data composed of data A to D and P. Also, the backup region stores backup data (A) to (D) and (P) of the copied important data. In this state, it is assumed that a failure has occurred in the HDDs #2 and #3 and data read error has occurred. In the data region, ordinary data c and d in the ordinary data region, data C and D in the important data region, and data (D) and (P) in the backup region are erroneous.

In this state, the data in the ordinary data region cannot be accessed, that is, the data is lost. The data in the important data region can be accessed through data D calculated from data A in the important data region, data B in the important data region, data (C) in the backup region, and data P in the important data region. In this period, a device state (data access attribute) is “access-disabled” in the ordinary data region and “read only” in the important data region.

FIG. 18B shows a state where data in the important data region is recovered after the defective HDD is replaced. The recovery process is performed manually by an operator or automatically in the system. The defective HDDs #2 and #3 are replaced with other HDDs 30 by the administrator. In these replaced HDDs #2 and #3, data C and D are recovered in the important data region. Further, the data (D) and (P) are recovered in the backup region.

In this state, since the data in the ordinary data region cannot be recovered, the initialization, that is, data clearing and parity matching process are performed. The defective data in the important data region is recovered by calculating data D from data A in the important data region, data B in the important data region, data (C) in the backup region, and data P in the important data region. In this period, the device state is the same as that of FIG. 18A.

FIG. 18C shows a state where a corresponding volume is recovered to old data through backup data stored before. The recovery process is performed by executing a command from, for example, the information processor 300. It is assumed that the prior backup data, that is, the old data is recorded in other backup means relating to the data stored in the HDD 30. This backup means may be a magnetic tape device, to which data is backed up. Conventionally, data in the HDD 30 is backed up to a magnetic tape device connected via a network to the disk array system.

In this state, the disk array system 100 recovers old data of a storage volume that corresponds to the failure based on the backup data recorded in a backup device such as a magnetic tape device. For example, the data composed of data a′ to d′ and p′ is stored in the ordinary data region. The data composed of data A′ to D′ and P′ is stored in the important data region. The data composed of data (A) to (D) and (P) is stored in the backup region. In the backup device, the backup data (old data) in the data region, for example, the data a to d and p are stored. By executing a command from the information processor 300, the old data is copied from the backup device to the data region and recovered in the HDD 30. In this manner, the data in the ordinary data region and the important data region are overwritten by the old data. Note that, at this time, data in the important data region can be accessed by the data response to the backup region. In this period, the device is in a state of “under recovery process”, the ordinary data region is in a state of “access-disabled”, and the important data region is in a state of “read only”.

FIG. 18D shows a state where data in the important data region is recovered by using the most recent data in the backup region. This recovery requires an operation by the operator. The controller 10 overwrites the most recent backup data A to D and P in the backup region into the important data region. Note that they are written to the locations corresponding to those at the time of the backup process. By doing so, the data in the important data region is recovered to the most recent data. The data in the ordinary data region is old data. Further, it is also possible to conversely overwrite old data stored in the important data region into the backup region, thereby returning the most recent data in the backup region to the old data. In this period, the device state is in a state of “read/write enabled” in the ordinary data region and the important data region.

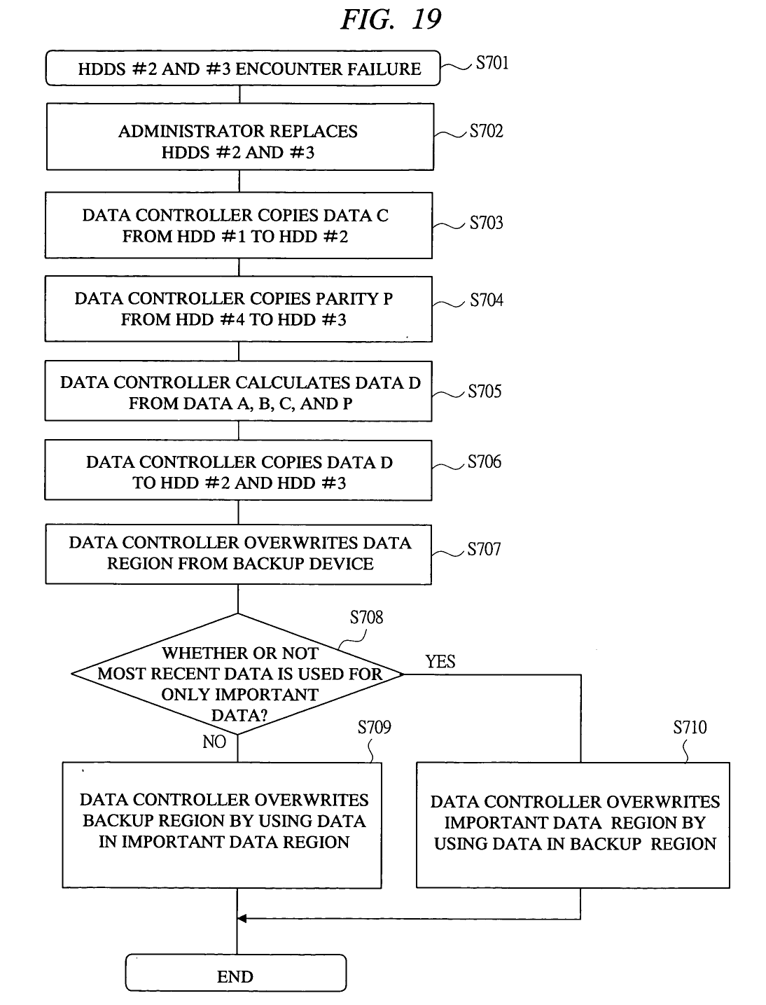

FIG. 19 is a flowchart for showing a process procedure corresponding to FIG. 18 in the case where two HDDs 30, for example, HDDs #2 and #3 have encountered a failure in a RAID group. In the disk array system 100, HDDs #2 and #3 encounter a failure (S701). The administrator replaces the HDDs #2 and #3 by other HDDs 30 (S702). The data controller 14 copies data C, which is backup data in the backup region, from HDD #1 into the important data region in the replaced HDD #2 (S703). Further, the data controller 14 copies data P, which is parity data in the important data region, from HDD #4 into the backup region in the replaced HDD #3 (S704).

The data controller 14 calculates data D from data A and B from HDDs #0 and #1, data C from the HDD #1, and data P from the HDD #4 (S705). The data controller 14 copies the calculated data D into the backup region in the replaced HDD #2 and the data region in the replaced HDD #3 (S706). The data controller 14 reads old data about the data region from the backup device and overwrites the data region by using the old data (S707). Then, the controller 10 determines whether the most recent data is to be used only for the important data (S708). When the most recent data is used (YES), the data controller 14 overwrites data in the important data region by using data in the backup region (S709). When the most recent data is not used (NO), the data controller 14 overwrites the data in the backup region by using the data in the important data region (S710), and the process ends.

### Fourth Embodiment

Next, a disk array system of the fourth embodiment of the present invention will be described. In a backup method of the fourth embodiment, based on the method of the third embodiment, the attributes of the data stored in the HDD 30 are specified from a host information processor 300 or the like to a disk array system 100 so that various kinds of processes including the backup process can be performed automatically for the data having the specified attributes.

The disk array system 100 of the fourth embodiment may be a network storage system (NAS system) that is compatible with an NAS or the like which is accessed by an information processor 300 such as a host computer by specifying a path/file name. In this embodiment, by registering attributes such as a folder name and a file extension in the disk array system 100, various kinds of processes such as automatic compression are automatically performed for the file having the specified attributes, and therefore, a storage capacity can be efficiently used and data reliability can be improved. In the system according to this embodiment, it is possible to clearly specify important data even more actively than the example of the third embodiment by utilizing the attribute table.

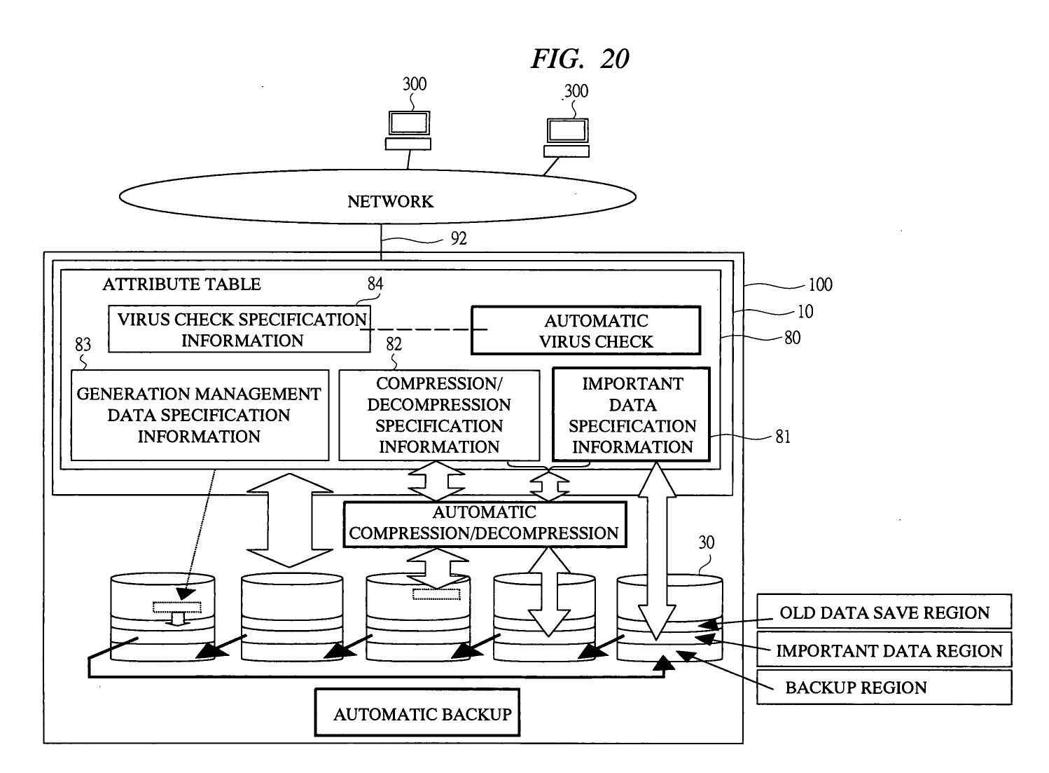

FIG. 20 shows a functional block configuration of the disk array system 100 (NAS system) of the fourth embodiment. An overall computer system has such a configuration in which the information processor 300 to be a host and the disk array system 100 (NAS system) are connected to a network such as an SAN or an LAN compatible with the NAS. The disk array system 100 is connected to this network through an interface compatible with an FC or Ethernet (registered trademark). The information processor 300 places a file access compatible with the NAS to the disk array system 100 through the network. This file access includes the specification of a path/file name.

The disk array system 100 has a hardware configuration compatible with the NAS. The controller 10 performs software process to realize the service provision as the NAS and the process using this backup method. The configuration and the function itself as the NAS are of the conventional technologies.

The controller 10 performs the attribute registration process and the automatic process in accordance with the attributes of the data that are determined in response to data access from the information processor 300. The controller 10 holds an attribute table 80, which is information for registering the attributes, in a memory.

The attribute table 80 contains important data specification information 81 as attribute registration information. Further, it also contains specification information for various kinds of processes such as compression/decompression specification information 82, generation management data specification information 83, and virus check specification information 84. The attribute table 80 is held in the memory of the controller 10 when the system is operating normally. Further, the attribute table 80 is saved/backed up in a system region on the side of the HDD 30 at, for example, a predetermined trigger and is loaded into the memory from the system region on the side of the HDD 30 at a predetermined trigger.

In the attribute table 80, the attributes of a file and data to be processed are described. The attributes to be described include, for example, a folder name/file or a part thereof, for example, “CMP*” which is the specification for all of the files of “CMP*”, a file extension, a creation user (user/host identification information, IP address, and the like), permission information such as “read only”, an access frequency, and the number of accesses (corresponds to the third embodiment).

A storage region of the HDD 30 includes the above-describe data region and a backup region. The data region has an important data region therein. Further, an old data save region is provided for generation management.

The important data specification information 81 is set to specify important data to be stored in the important data region in the data region of the HDD 30 in accordance with the backup process of the important data shown in the third embodiment. The file and data concerned in this specification are stored/allocated in the important data region by the controller 10 and the control for automatically backing up the data from the important data region into the backup region is performed at a predetermined trigger.

The compression/decompression specification information 82 is set to automatically compress/decompress the data to be stored in the HDD 30. In the disk write, a file and data concerned in this specification are automatically compressed by automatic compression/decompression means provided in the disk array system 100, for example, a compression/decompression program or a compression/decompression circuit provided in the controller 10 and are written to the storage region of the HDD 30. Further, in the disk read, the data read from the storage region of the HDD 30 is automatically decompressed by this compression/decompression means and transferred to the host.

The generation management data specification information 83 is set to specify generation management process (conventional technology) to manage the data based on its generation or version. As for a file and data concerned in this specification, the controller 10 performs the control as follows. That is, the data is saved into an old data save region in the data region to store each generation of data. The virus check specification information 84 is set to specify automatic virus check process performed by the controller 10.

It is also possible to use these various processes in combination. For example, it is possible to perform the backup process and automatic compression/decompression process for the important data by the specification of the important data specification information 81 and the compression/decompression specification information 82 while performing the automatic virus check process for all the data.

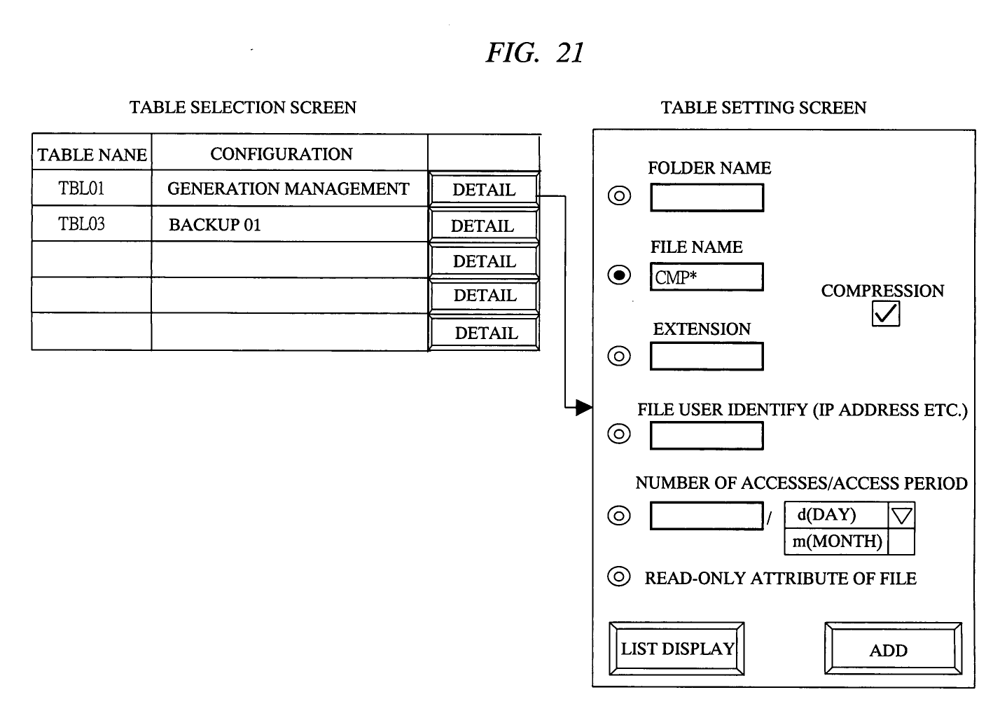

FIG. 21 shows an example of an important data selection screen in the fourth embodiment. A management device connected to the disk array system 100 executes a management program for configuring the settings of the processes so that the user or the administrator can make the settings. The hardware and software configurations for these settings are the same as those of the above-described embodiments. An operator such as the administrator displays a table selection screen concerning the settings of the important data specification information 81 shown on the left side of FIG. 21 on the management device. On the table selection screen, a list of attribute table names and their kind of configuration is displayed. For example, in relation to the attribute table name “TBL03”, the process named “backup 01”, especially, an internal automatic process is set. When the operator selects an attribute table to be set from the list and presses a detail button, a table setting screen is displayed. The operator sets and inputs the attributes of important data on the table setting screen. For example, in the setting of a file to be processed in the “backup 01”, the items to be set include a folder name, a file name, a file extension, a file used identifier, the number of accesses/access period, read-only file attribute, and the operator selects necessary items to set them. As an example of the setting, the specification for the file name “CMP*” and check the automatic compression/decompression process button for the relevant file are set. By this setting, a file whose file name is “CMP*” (“*” indicates a wild card character) is specified as important data and is subject to the automatic backup process and the compression/decompression process in the disk array system 100. In the setting of the number of accesses/access period, the data corresponding to the set number of times or access period is subject to the process. Further, the setting of the read-only is automatically made when set the attribute of file access permission is read-only. When a list display button is selected, a list of information about files and data which correspond to the settings of the attribute table is displayed. The operator inputs the settings on the screen and presses an add button to register them.

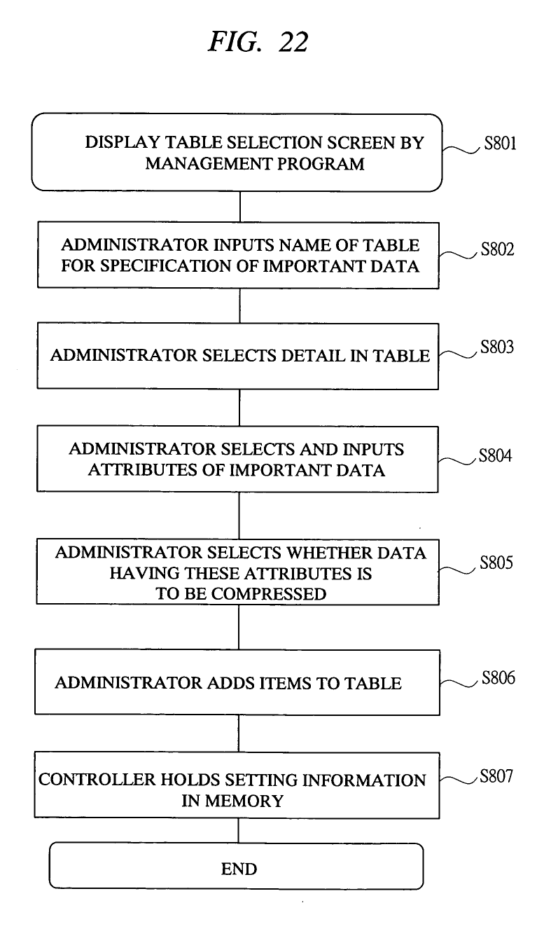

FIG. 22 shows an example of a procedure for setting the important data specification information 81. The administrator, on the management device, displays the table selection screen through the process of the management program (S801). The administrator inputs a name of an attribute table for specification of important data on the table selection screen to create an attribute table (S802). Then, the administrator presses the detail button of the created attribute table to display the table setting screen (S803). For example, the attribute table “TBL03” corresponding to the process of “backup 01” is created. The administrator selects and inputs the attributes of desired important data to be processed on the table setting screen (S804). For example, the administrator selects the item “file name” to input a file name. Then, the administrator selects other processes to which the data having these specified attributes is applied. For example, the administrator checks the radio button of the item of “automatic compression/decompression” (S805). After inputting the necessary settings, the administrator presses the “add” button (S806). By doing so, the settings in this attribute table 80 are validated. The controller 10 stores and holds the setting information of the attribute table 80 in the memory (S807).

Not only the important data specification but also various settings relating to this backup method are made through setting processes in the management device and the like. An attribute table 80 that corresponds to the settings of various processes is created and held by the controller 10. The controller 10 references the attribute table 80 when accessing data in the HDD 30 to determine whether the data to be accessed is subject to the specified process. When the data corresponds to the specified attributes, a specified process such as the automatic backup process is performed to this data.

According to the fourth embodiment, since it is possible to perform various kinds of processes including the automatic backup process in the disk array system 100 with using the data specified by the user, that is, specified from the information processor 300 as important data, a degree of freedom for securing the data reliability can be improved.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be applied to a computer system that stores data in a group of storage devices.

What is claimed is:

1. A disk array system connected to a host information processor, comprising: a storage device; and a controller for controlling data storage to a storage region in said storage device,
wherein said controller stores first data transmitted from said host information processor into a first storage region which is a part of the region of one or more storage devices in an overall storage region composed of a plurality of storage devices,
stores backup data of said first data into a second storage region which is a part of the region of one or more storage devices in such a manner that the backup data may be stored in the storage device different from a storage destination of said first data, and
uses the storage region in which said backup data is stored as a region for storing the newly transmitted data when a capacity of a free space region for storing data newly transmitted from said host information processor is reduced below a predetermined value in said overall storage region.

2. The disk array system according to claim 1,
wherein said controller stripes said first data and performs parity process as RAID control,
stores striping data of said first data created through said RAID control into a first storage region which is a part of the region of two or more storage devices in said overall storage region, and
stores backup data of said striping data into a second storage region which is a part of the region of two or more storage devices so that the backup data of said striping data can be stored in the storage device different from a storage destination of said striping data.

3. The disk array system according to claim 1,
wherein, when reading said first data from said storage device, said controller obtains normal data from said first storage region or said second storage region by using at least either one of said first data and said backup data.

4. The disk array system according to claim 1,
wherein said controller stores said backup data at a location in an adjacent storage device shifted from the storage device of said first data in said overall storage region.

5. The disk array system according to claim 1,
wherein said controller provides a data region for storing said first data and a backup region for storing said backup data in said overall storage region and continues to store said backup data until said backup region is used up, and when said data region is used up, it starts to use said backup region to store said first data.

6. The disk array system according to claim 1,
wherein said controller divides said overall storage region into region units each having a predetermined size for storing said first data and said backup data and holds, in a memory, correlation information by means of conversion between addresses of these divided regions and an address system in said storage device and information indicating a type of data stored in said divided regions, and
when storing said first data or backup data into said overall storage region, said controller performs conversion between an original storage destination address and an address of said divided region so as to preserve consecutive free space regions and then sequentially stores the data with using said divided region as a unit.

7. The disk array system according to claim 1,
wherein, when a failure occurs in any one of said plurality of storage devices or storage regions in which said first data or backup data is stored, said controller reads the backup data or the first data in the corresponding different storage device or storage region to recover defective data.

8. The disk array system according to claim 1,
wherein, in a first backup mode, said controller conducts such control as to store said first data sequentially from a top region toward a last region in said overall storage region and store said backup data sequentially from the last region toward the top region in said overall storage region, and it releases the regions in which said backup data is stored sequentially from more recent ones.

9. The disk array system according to claim 1,
wherein, in a second backup mode, said controller conducts such control as to store said first data sequentially from a top region toward a last region in said overall storage region and store said backup data sequentially from an intermediate region toward the last region in said overall storage region, and it releases the regions in which said backup data is stored sequentially from less recent ones.

10. The disk array system according to claim 1,
wherein said controller conducts such control as to distribute accesses to the storage devices in which said first data is stored and those in which said backup data is stored so that the accesses are not concentrated on a particular one of them when an operation to input/output said first data is performed to said plurality of storage devices.

11. A disk array system connected to a host information processor, comprising: a storage device; and a controller for controlling data storage to a storage region in said storage device,
wherein said controller performs a process to store first data to be stored in said storage device into a first storage region which is a part of the region of one or more storage devices in an overall storage region composed of a plurality of storage devices and store backup data of said first data into a second storage region which is a part of the region of one or more storage devices in such a manner that said backup data may be stored in the storage device different from that of said first data, and
said controller performs a process to set a pair of a large-size data and a small-size data as said first data, store backup data of said large-size data in a free space region of the storage device in which said small-size data is stored, and store backup data of said small-size data in a free space region of the storage device in which said large-size data is stored.

12. The disk array system according to claim 11,
wherein said controller performs a process to set system data containing data of an OS or an application and ordinary data as said pair, store backup data of said system data in a free space region of the storage device in which said ordinary data is stored, and store backup data of said ordinary data in a free space region of the storage device in which said system data is stored.

13. A disk array system connected to a host information processor, comprising: a storage device; and a controller for controlling data storage to a storage region in said storage device,
wherein said controller provides storage regions in accordance with importance levels of storage data in an overall storage region composed of a plurality of storage devices,
performs a process to store first data to be stored in said storage device into a first storage region which is a part of the region of one or more storage devices,
performs a process to select the storage region in which said first data is stored by determining the importance level of said first data and move said first data to the storage region that corresponds to the importance level thereof in response to change in said importance level, and
performs a process to automatically store backup data of the first data into a second storage region which is a part of the region of one or more storage devices in such a manner that said first data and its backup data are stored into the different storage devices when said first data is stored to the storage region that corresponds to a high importance level.

14. A disk array system connected to a host information processor, comprising: a storage device; and a controller for controlling data storage to a storage region in said storage device,
wherein said controller provides storage regions in accordance with importance levels of storage data in an overall storage region composed of a plurality of storage devices,
performs a process to hold, in a memory of said controller, a table in which specification of attributes of data having a high importance level in the first data to be stored in said storage device is set based on settings from said information processor,
performs a process to determine an importance level of said first data transmitted from said host information processor by referencing said table,
performs a process to select a storage region to which said first data is stored according to said importance level and store said first data therein, and
performs a process to automatically store backup data of the first data into a second storage region which is a part of the region of one or more storage devices in such a manner that said first data and its backup data may be stored into the different storage devices when said first data is stored in the storage region that corresponds to a high importance level.

15. The disk array system according to claim 14,
wherein said controller performs a process to hold, in a memory of said controller, a table in which specification of attributes of data to be subject to particular process including the process to store said backup data in said first data and specification of the particular process to be performed to the data having said attributes are set based on settings from said information processor,
performs a process to determine whether the data is to be subject to said particular process by referencing said table when said first data is stored in said storage device, and
performs a process to automatically perform said particular process including the process to store said backup data to the data to be subject to said particular process.
